(19) United States
(12) Patent Application Publication
(10) Pub. No.: US 2025/0338471 A1
(43) Pub. Date: Oct. 30, 2025

(54) MANUFACTURING METHOD OF MEMORY DEVICE

(71) Applicant: Yangtze Memory Technologies Co., Ltd., Wuhan (CN)

(72) Inventors: Yaqin LIU, Wuhan (CN); Liang CHEN, Wuhan (CN); Shiqi HUANG, Wuhan (CN); Zongliang HUO, Wuhan (CN)

(21) Appl. No.: 18/933,261

(22) Filed: Oct. 31, 2024

(30) Foreign Application Priority Data
Apr. 29, 2024 (CN) 202410537509.3

(51) Int. Cl. H10B 12/00

(52) U.S. Cl. CPC H10B 12/036; H10B 12/482; H10B 12/488; H10B 12/50

(57) ABSTRACT

Examples of the present application provide manufacturing methods of a memory device. including: One example method comprises forming a first semiconductor structure including a memory cell array, forming a second semiconductor structure including first control circuits and at least part of a peripheral circuit distributed in a gap of the first control circuits, wherein the first semiconductor structure and the second semiconductor structure are disposed as being stacked and connected. The example method further comprises forming a first interconnection layer on a side of the second semiconductor structure away from the first semiconductor structure, and forming connection structures, each connection structure penetrating through a portion of the second semiconductor structure, with one end being connected with the at least part of the peripheral circuit in the gap, and the other end being connected with the first interconnection layer.

### CROSS-REFERENCE TO RELATED APPLICATIONS

This application claims priority to Chinese Patent Application No. 202410537509.3, filed on Apr. 29, 2024, which is hereby incorporated by reference in its entirety.

### TECHNICAL FIELD

Examples of the present application relate to the technical field of semiconductor, and particularly to a manufacturing method of a memory device.

### BACKGROUND

A memory device is a storage apparatus for storing information in modern information technologies. However, as requirements of people for the storage apparatus become increasingly high, there is still much room for improvements to the memory device.

### SUMMARY

In view of this, examples of the present application provide a manufacturing method of a memory device, comprising: forming a first semiconductor structure comprising a memory cell array; forming a second semiconductor structure comprising at least a plurality of first control circuits and at least part of a peripheral circuit distributed in a gap of the plurality of first control circuits, wherein the first semiconductor structure and the second semiconductor structure are disposed as being stacked and connected; forming a first interconnection layer on a side of the second semiconductor structure away from the first semiconductor structure; and forming a plurality of connection structures, each connection structure penetrating through a portion of the second semiconductor structure, with one end being connected with the at least part of the peripheral circuit in the gap, and the other end being connected with the first interconnection layer.

In some examples, forming the first semiconductor structure, the second semiconductor structure and the first interconnection layer comprises: forming the second semiconductor structure on a first surface of a first substrate; forming a second interconnection layer on the second semiconductor structure; forming the first semiconductor structure on the second interconnection layer, wherein the first semiconductor structure and the second semiconductor structure are connected by the second interconnection layer; and forming the first interconnection layer on a second surface of the first substrate, wherein the first surface and the second surface are two surfaces disposed oppositely along a thickness direction of the first substrate.

In some examples, forming the first semiconductor structure, the second semiconductor structure and the first interconnection layer comprises: forming the second semiconductor structure on a first surface of a first substrate; sequentially forming a third interconnection layer and a first bonding layer that are stacked on the second semiconductor structure; forming the first semiconductor structure on a second substrate; sequentially forming a fourth interconnection layer and a second bonding layer that are stacked on the first semiconductor structure; bonding the first bonding layer and the second bonding layer, wherein the first semiconductor structure and the second semiconductor structure are connected by the third interconnection layer, the first bonding layer, the second bonding layer, and the fourth interconnection layer; and forming the first interconnection layer on a second surface of the first substrate, wherein the first surface and the second surface are two surfaces disposed oppositely along a thickness of the first substrate.

In some examples, the memory cell array comprises a plurality of memory banks, each memory bank comprising a plurality of memory blocks; one of the first control circuits is connected with one of the memory blocks, and the peripheral circuit is connected with all the memory banks; the at least part of the peripheral circuit comprises a plurality of first portions and one second portion; forming the at least part of the peripheral circuit comprises: forming one of the first portions and one of the first control circuits at a position in the second semiconductor structure that overlaps a region for disposing each of the memory blocks; and forming the second portion at a position in the second semiconductor structure that overlaps the gap between adjacent ones of the memory blocks, wherein at least one of the first portion or the second portion is connected with the first interconnection layer by the plurality of connection structures.

In some examples, the first control circuits comprise a sensing amplifier and a word line driver; the sensing amplifier is connected with a bit line in the memory block; and the word line driver is connected with a word line in the memory block.

In some examples, forming the second semiconductor structure comprises: forming the sensing amplifier in a first region and a second region; and forming the word line driver in a third region and a fourth region, wherein the first region and the second region both extend along a first direction and are disposed as being staggered along a second direction, the third region and the fourth region both extend along the second direction and are disposed as being staggered along the first direction, the first direction is perpendicular to a direction in which the bit line extends, and the second direction is perpendicular to a direction in which the word line extends.

In some examples, a boundary of the first region contacts a boundary of the third region, and a boundary of the second region contacts a boundary of the fourth region; a sum of dimensions of the boundary of the first region and the boundary of the third region along the first direction is a first dimension, a dimension of a boundary of the region for disposing the memory block along the first direction is a second dimension, and the first dimension is less than the second dimension.

In some examples, the memory device further comprises a first contact connected with the word line, a second contact connected with the bit line, a third contact connected with the sensing amplifier, and a fourth contact connected with the word line driver; the method further comprises: forming the first contact and the second contact; and forming the third contact and the fourth contact, wherein the second contact and the third contact, as well as the first contact and the fourth contact, are connected at least by the interconnection layer between the first semiconductor structure and the second semiconductor structure.

In some examples, the method further comprises: forming a power supply line in the first interconnection layer.

In some examples, the second semiconductor structure further comprises a plurality of second control circuits, one of the second control circuits being connected with one of the memory banks; and forming the second semiconductor structure further comprises: forming the at least part of the peripheral circuit and the plurality of second control circuits in the gap of the plurality of first control circuits, wherein the second control circuits comprise a row decoding circuit and a column decoding circuit.

In some examples, forming the second control circuit comprises: forming the second control circuit at a position in the second semiconductor structure that overlaps the gap between adjacent ones of the memory banks.

In some examples, the method further comprises: forming a pad electrically connected with the first interconnection layer on a side of the first interconnection layer away from the second semiconductor structure.

In some examples, the first surface of the first substrate comprises a plurality of active regions spaced apart by isolation regions; and the method further comprises: forming the connection structures penetrating through the first substrate at boundaries of the active regions and in the isolation regions.

In some examples, forming the first semiconductor structure comprises: forming a plurality of bit lines extending along a second direction; forming a plurality of semiconductor pillars on surfaces of the bit lines, each semiconductor pillar extending along the thickness direction of the first substrate; forming a plurality of word lines extending along a first direction, each word line being located on at least one side surface of the semiconductor pillar, wherein the first direction and the second direction are both perpendicular to the thickness direction of the first substrate; and forming a storage structure on a surface of each of the semiconductor pillars away from the bit line.

In some examples, the method further comprises: providing a third substrate; bonding the third substrate to the storage structure to form a bonding structure; flipping the bonding structure to expose the second surface of the first substrate; and removing the third substrate after forming the first interconnection layer on the second surface of the first substrate.

In some examples, forming the first semiconductor structure comprises: forming a plurality of storage structures on the second substrate; forming a semiconductor pillar on a surface of each of the storage structures away from the second substrate, the semiconductor pillar extending along a thickness direction of the second substrate; forming a plurality of word lines extending along a first direction, each word line being located on at least one side surface of the semiconductor pillar; and forming a bit line on a surface of the semiconductor pillar away from the storage structure, the bit line extending along a second direction, wherein the first direction and the second direction are both perpendicular to the thickness direction of the second substrate.

In some examples, the memory device comprises a dynamic random access memory; the storage structure comprises a capacitor; and the capacitor comprises a cup-shaped capacitor, a cylindrical capacitor, or a pillar-shaped capacitor.

In some examples, the method further comprises: forming the plurality of storage structures arranged in a square or hexagon.

In some examples, forming the word line comprises: forming the word line located on one side surface of the semiconductor pillar; forming the word line located on two side surfaces of the semiconductor pillar that are disposed oppositely; or forming the word line surrounding the side surfaces of the semiconductor pillar.

In some examples, a material of the semiconductor pillar comprises indium gallium zinc oxide.

In the examples of the present application, the first semiconductor structure (comprising the memory cell array) and the second semiconductor structure (comprising the first control circuits and the peripheral circuit) disposed as being stacked are formed, so that the storage density of the memory device can be increased compared to the solution in which the two are disposed in juxtaposition. Through wiring on a back side of the second semiconductor structure and connection to at least part of the peripheral circuit via the connection structures penetrating through the second semiconductor structure, the at least part of the peripheral circuit can be laid out in the gap of the first control circuits dispersedly. Compared with directly disposing the peripheral circuit in a complete region integrally, an additional area brought by the peripheral circuit in the second semiconductor structure is reduced directly. As such, the dimension of the memory device may be reduced, and the storage density of the memory device may be further improved.

### BRIEF DESCRIPTION OF THE DRAWINGS

FIG. 1 is a schematic diagram of a constituent structure of an example dynamic random access memory according to an example of the present application;

FIG. 2 is a top view I of a distribution of a memory cell array and a peripheral circuit in an example memory device according to an example of the present application;

FIG. 3A is a top view II of the distribution of the memory cell array and the peripheral circuit in the example memory device according to an example of the present application;

FIG. 3B is an example expansion schematic diagram based on FIG. 3A according to an example of the present application;

FIG. 3C is an example schematic enlarged view of a region PZ based on FIG. 3A according to an example of the present application;

FIG. 4A is a top view III of the distribution of the memory cell array and the peripheral circuit in the example memory device according to an example of the present application;

FIG. 4B is a top view V of the distribution of the memory cell array and the peripheral circuit in the example memory device according to an example of the present application;

FIG. 5A is an example schematic enlarged view of a region QZ based on FIG. 4A or FIG. 4B according to an example of the present application;

FIG. 5B is an example schematic enlarged view of a region RZ based on FIG. 5A according to an example of the present application;

FIG. 6 is a schematic cross-sectional view I of a memory device provided by examples of the present application;

FIG. 7 is a schematic cross-sectional view II of a memory device provided by examples of the present application;

FIG. 8 is a planar layout diagram I of a first control circuit corresponding to one memory block of the memory device provided by examples of the present application;

FIG. 9 is a planar layout diagram II of the first control circuit corresponding to one memory block of the memory device provided by examples of the present application;

FIG. 10A is a planar layout diagram I of a memory cell array of the memory device provided by examples of the present application;

FIG. 10B is a schematic cross-sectional view of FIG. 10A along a cross section C-C;

FIG. 11A is a planar layout diagram II of the memory cell array of the memory device provided by examples of the present application;

FIG. 11B is a schematic cross-sectional view of FIG. 11A along the cross section C-C;

FIG. 12A is a planar layout diagram III of the memory cell array of the memory device provided by examples of the present application;

FIG. 12B is a schematic cross-sectional view of FIG. 12A along the cross section C-C;

FIG. 13A is a planar layout diagram I of a storage structure of the memory device provided by examples of the present application;

FIG. 13B is a planar layout diagram II of a storage structure of the memory device provided by examples of the present application;

FIG. 14 is a flow diagram of a manufacturing method of a memory device provided by examples of the present application;

FIG. 15A to FIG. 15K are schematic cross-sectional views I in a process of forming a memory device provided by examples of the present application; and

FIG. 16A to FIG. 16D are schematic cross-sectional views II in a process of forming a memory device provided by examples of the present application.

### DETAILED DESCRIPTION

The technical solutions in implementations of the present application will be described below clearly and completely in conjunction with the implementations and the drawings of the present application. Apparently, the described implementations are merely part, but not all, of the implementations of the present application. All other implementations obtained by those of ordinary skills in the art based on the implementations in the present application without creative work shall fall within the protection scope of the present application.

In the description below, many specific details are presented to provide a more thorough understanding of the present application. However, it is apparent to those skilled in the art that the present application may be carried out without one or more of these details. In other examples, in order to avoid confusion with the present application, some technical features well-known in the art are not described. That is, all the features of the actual examples are not described herein, and well-known functions and structures are not described in detail.

In the drawings, the sizes of a layer, a region, and an element and their relative sizes may be exaggerated for clarity. Like reference numerals denote like elements throughout.

It is to be understood that when an element or a layer is referred to as being “on”, “adjacent to”, “connected to”, or “coupled to” other elements or layers, it may be directly on, adjacent to, connected to, or coupled to the other elements or layers, or one or more intervening elements or layers may be present. In contrast, when an element is referred to as being “directly on”, “immediately adjacent to”, “directly connected to”, or “directly coupled to” other elements or layers, no intervening elements or layers are present. It is to be understood that, although the terms first, second, and third, etc., may be used to describe various elements, components, areas, layers and/or portions, these elements, components, areas, layers and/or portions should not be limited by these terms. These terms are only used to distinguish one element, component, area, layer or portion from another element, component, area, layer or portion. Therefore, without departing from the teaching of the present application, a first element, component, area, layer, or portion discussed below may be represented as a second element, component, area, layer, or portion. While the second element, component, area, layer, or portion is discussed, it does not mean that the first element, component, area, layer, or portion is necessarily existent in the present application.

The spatially relative terms, such as “beneath”, “below”, “lower”, “under”, “above”, “upper”, and the like, may be used herein for ease of description to describe one element or feature's relationship to other elements or features as illustrated in the figures. It is to be understood that in addition to orientations shown in the drawings, the spatial relationship terms are intended to further comprise different orientations of a device in use and operation. For example, if the device in the drawings is turned over, then an element or a feature described as being “below other elements”, or “under other elements”, or “beneath other elements” will be orientated as being “above” the other elements or features. Thus, the example terms “below” and “beneath” may comprise both upper and lower orientations. The device may be orientated otherwise (rotated by 90 degrees or at other orientations), and the spatial descriptive terms used herein are interpreted accordingly.

A purpose of the terms used herein is only to describe the examples and not as a limitation to the present application. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any and all combinations of related items listed.

In order to understand the present application thoroughly, detailed operations and detailed structures will be proposed in the following description to set forth the technical solution of the present application. The detailed descriptions of the examples of the present application are as follows. However, the present application may also have other implementations in addition to these detailed descriptions.

The memory device involved in the examples of the present application may be a Random Access Memory (RAM), such as a Dynamic Random Access Memory (DRAM), a synchronous DRAM (SDRAM), a static RAM (SRAM), a double data rate SDRAM (DDR SDRAM), a DDR2 SDRAM, a DDR3 SDRAM, a phase change RAM (PRAM), a magnetic RAM (MRAM), or a resistive RAM (RRAM), and the like. The following illustration is performed only using the DRAM as an example.

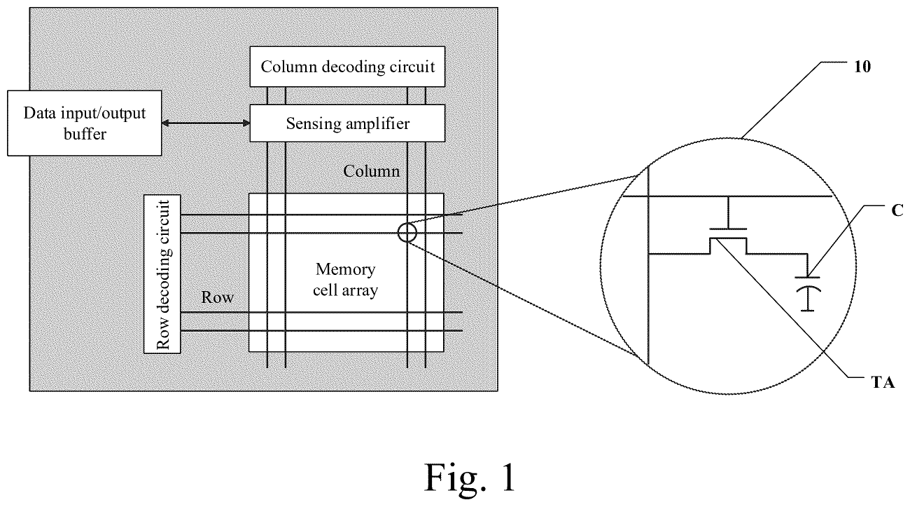

FIG. 1 is a schematic diagram of a constituent structure of an example dynamic random access memory according to an example of the present application.

On the right side of FIG. 1, an illustrative circuit of the memory cell in the DRAM is shown. The DRAM comprises at least one DRAM die, and each DRAM die comprises a memory cell array. The memory cell array comprises a plurality of memory cells 10 arranged in an array, and each memory cell 10 comprises one Transistor (TA) and one Capacitor (C). A main action principle of the memory cell is to use an amount of charge stored in the capacitor to represent whether a binary bit is 1 or 0. The memory cells are arranged in an array, which may be regarded as a typical mesh structure. The memory cell array designates an address using a row and a column. By designating an intersection of the row and the column (by designating a row address and a column address of the DRAM), a memory controller may access each memory cell in the DRAM die independently, and perform a read, write, or refresh operation on data stored in the memory cell.

On the left side of FIG. 1, the memory cell array, a word line (row), a bit line (column), part of control circuit, and part of a peripheral circuit in the DRAM are shown. It is to be noted that a row decoding circuit in the control circuit selects a word line in response to an address input to the row decoding circuit, so as to select a row of the memory cells to be accessed. The row decoding circuit decodes the input address and enables (activates) the word line corresponding to the decoded address. A column decoding circuit in the control circuits selects one or more bit lines to input output data of a user into a portion of the row of the memory cells corresponding to the selected word line.

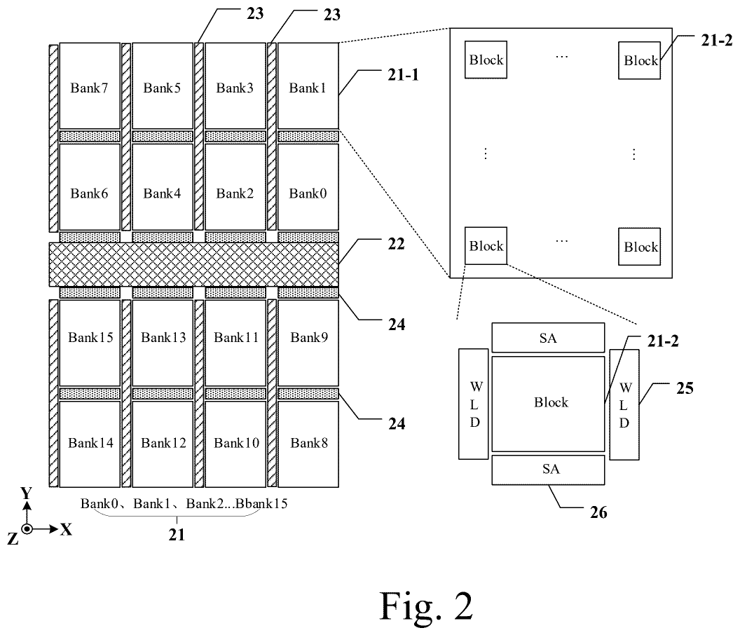

FIG. 2 is a top view I of a distribution of a memory cell array and a peripheral circuit in an example memory device according to an example of the present application. One layout pattern of the memory device is described in detail below in conjunction with FIG. 2. Before introducing the memory device illustrated in FIG. 2, directions that may be used in the subsequent description are defined first. Two directions parallel to a plane of a substrate (or a semiconductor structure) are defined as a first direction (i.e., an X direction) and a second direction (i.e., a Y direction). A third direction (i.e., a Z direction) is defined as a direction perpendicular to the plane of the substrate (or the semiconductor structure). In some examples, the X direction, the Y direction and the Z direction may be perpendicular to each other pairwise.

In an example, as shown in FIG. 2, the memory cell array 21 and the peripheral circuit 22 are disposed in juxtaposition. In an implementation, the memory cell array 21 comprises a plurality of (e.g., 16) memory banks 21-1 (Bank0-Bank15), each memory bank 21-1 comprising a plurality of memory blocks 21-2. A Sensing Amplifier (SA) 26 and a Word Line Driver (WLD) 25 corresponding to each memory block 21-2 are disposed oppositely around the memory block, and a column decoding circuit 24 and a row decoding circuit 23 corresponding to each memory bank are disposed on two sides of the memory bank. Every plurality of (e.g., 4) memory banks form one memory bank row, and the peripheral circuit 22 corresponding to all the memory banks is disposed between two memory bank rows in the middle. It is to be noted that the number of the memory banks and a positional relationship of circuits in FIG. 2 are for example purposes only and are not used for limiting the number of memory banks or positional relationship of circuits in the memory device in the present application.

Here and hereafter, the peripheral circuit 22 is a control circuit corresponding to all the memory banks, that is, all the memory banks share the peripheral circuit 22. The peripheral circuit 22 may include, but is not limited to, a command buffer, a command decoder, an address buffer, a data buffer, and a mode register, etc. A first control circuit is a control circuit corresponding to the memory block, such as the SA and WLD mentioned above. That is, each memory block corresponds to a set of SA and WLD, and in consideration of the convenience of wiring, the set of SA and WLD corresponding to each memory block is disposed next to the respective memory block. A second control circuit is a control circuit corresponding to the memory bank, such as the column decoding circuit and row decoding circuit mentioned above. That is, each memory block corresponds to a set of column decoding circuit and row decoding circuit, and in consideration of the convenience of wiring, the set of column decoding circuit and row decoding circuit corresponding to each memory bank is disposed next to the respective memory bank.

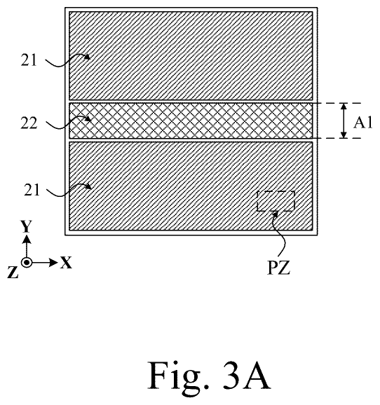

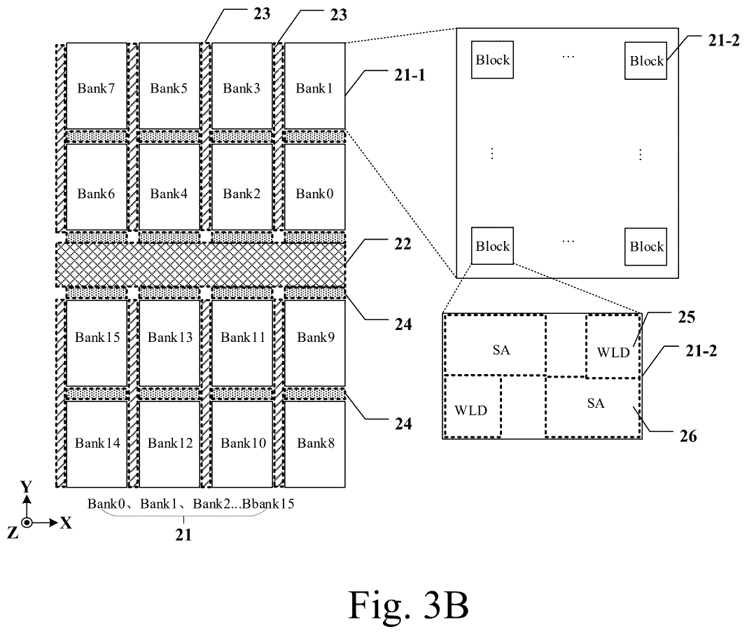

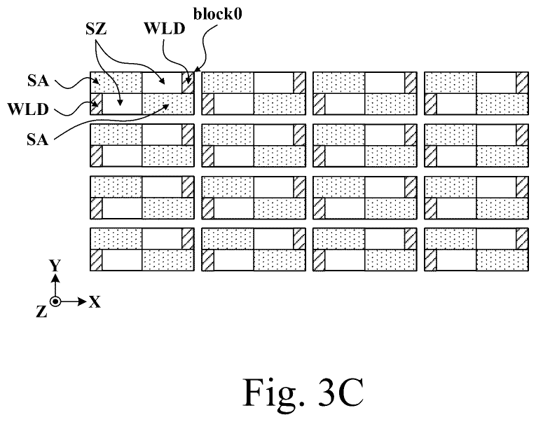

FIG. 3A is a top view II of the distribution of the memory cell array and the peripheral circuit in the example memory device according to an example of the present application. FIG. 3B is an example expansion schematic diagram based on FIG. 3A according to an example of the present application. FIG. 3C is an example schematic enlarged view of a region PZ based on FIG. 3A according to an example of the present application.

Referring to FIG. 3A and FIG. 3B, the memory device may be a structure with a first semiconductor structure comprising a memory cell array and a second semiconductor structure comprising a peripheral circuit that are stacked along the Z direction, wherein FIG. 3B differs from FIG. 2 in that the SA 26 and the WLD 25 of each memory block 21-2 are both disposed below each memory block. Accordingly, in the enlarged view corresponding to each memory block 21-2 in FIG. 3B, a solid line denotes an enlarged portion of the memory block 21-2, and a dashed line denotes the SA 26 and the WLD 25 corresponding to the memory block 21-2 that are at a position directly below the memory block 21-2. It is to be noted that in some other examples, positions of the memory block 21-2 and the SA 26 and WLD 25 corresponding to the memory block 21-2 may be interchanged vertically. The following illustration is performed only with an example in which the SA 26 and the WLD 25 are located below the memory block 21-2.

In FIG. 3A, the peripheral circuit 22 corresponding to all the memory banks is disposed on the second semiconductor structure. For the convenience of winding, a region in the middle of two memory cell arrays 21 disposed on the first semiconductor structure may be disposed as being spare, i.e., provided with no device, so that the peripheral circuit 22 located on the second semiconductor structure can be observed directly in the top view.

The region PZ in FIG. 3A is labeled with a dashed line, indicating that FIG. 3C shows disposing regions corresponding to the SA 26 and WLD 25 corresponding to the memory block 21-2, at a position directly below the 16 memory blocks 21-2, e.g., one memory block block0 corresponds to one SA located in two regions and one WLD located in two regions. In FIG. 3C, a plurality of SAs 26 and WLDs 25 are disposed in an array corresponding to the plurality of memory blocks 21-2 disposed in an array.

In the above example, the SA and WLD corresponding to each memory block may be directly laid out below the respective memory block without occupying an additional chip area. However, the above peripheral circuit is laid out on the periphery of an orthographic projection of the memory cell array in a plane (an X-Y plane) where the second semiconductor structure is located, occupying an additional area.

In the above example, considering that the area occupied by the peripheral circuit is typically large, placing the peripheral circuit dispersedly in separate regions that are spaced apart may cause wiring of an interconnection line of the peripheral circuit disposed dispersedly to be complicated, and the complicated wiring may conflict with wiring of the first control circuit and the second control circuit mentioned above, the control circuits are disposed concentratedly on the second semiconductor structure, and at this time, an area at a position of the first semiconductor structure corresponding to the peripheral circuit is substantially in a vacant and wasted condition. As the level of integration of a Complementary Metal Oxide Semiconductor (CMOS) increases, an area occupied by the first control circuit shrinks, and the area occupied by the first control circuit corresponding to each memory block is less than an area occupied by the memory block. As such, in addition to a layout of the first control circuit below the memory block, there is still a spare region with a relatively objective area. Accordingly, through layout planning, spare regions can be reasonably placed and joined together to form a relatively large region for placing at least part of the peripheral circuit.

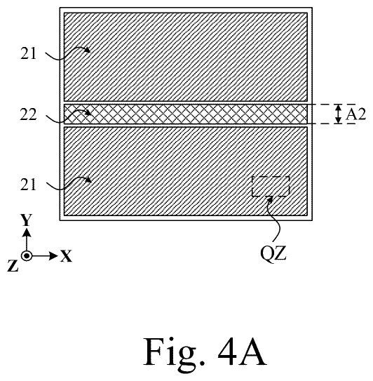

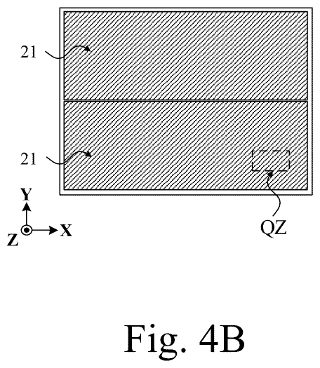

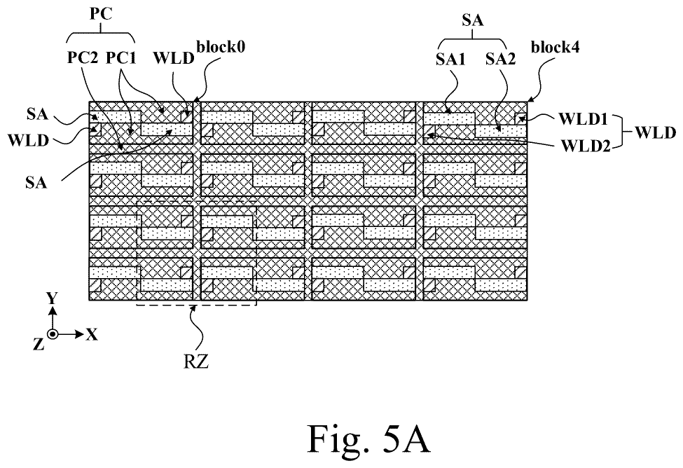

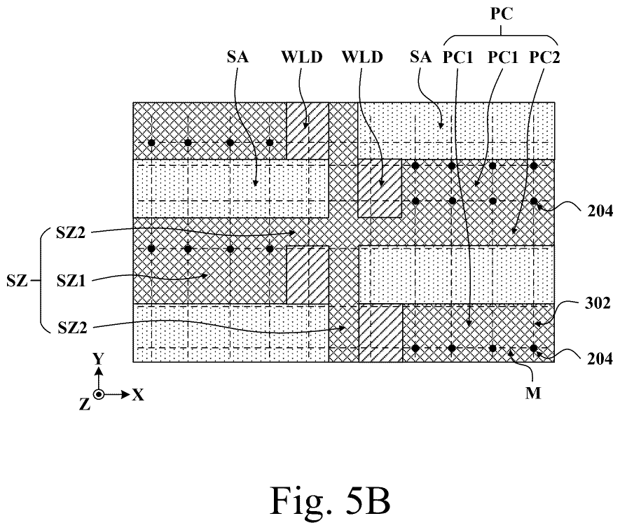

FIG. 4A is a top view III of the distribution of the memory cell array and the peripheral circuit in the example memory device according to an example of the present application. FIG. 4B is a top view V of the distribution of the memory cell array and the peripheral circuit in the example memory device according to an example of the present application. FIG. 5A is an example schematic enlarged view of a region QZ based on FIG. 4A or FIG. 4B according to an example of the present application. FIG. 5B is an example schematic enlarged view of a region RZ based on FIG. 5A according to an example of the present application.

In some examples, with reference to FIG. 4A, FIG. 4B, FIG. 5A, and FIG. 5B, compared with the memory device shown in FIG. 3A to FIG. 3C, in the provided memory device, the spare regions mentioned above can be utilized to place at least part of the peripheral circuit reasonably, directly reducing the additional area occupied by the peripheral circuit. At the same time, in the second semiconductor structure having the peripheral circuit and the first control circuit formed on a front side thereof, a line connecting the first control circuit with the memory cell array is laid out on the front side of the second semiconductor structure, and a line connecting the peripheral circuit dispersed in a gap of layout positions of the first control circuit is laid out on a back side of the second semiconductor structure, so as to avoid a conflict in the wiring of both lines, thereby achieving the purpose of saving the area without reducing the storage capacity or degrading the performance of the control circuits.

The memory device in FIG. 3A may be used as a comparison group for the memory device in FIG. 4A and FIG. 4B. The memory device in FIG. 4A and FIG. 4B may be understood as, provided that the storage capacity of the memory device remains unchanged, placing at least part of the peripheral circuit directly in the spare regions below the memory block of the memory device in FIG. 3A, or in the spare regions below the memory block that are made larger due to the reduction in dimensions of the first control circuit. Part of the peripheral circuit in FIG. 4A is placed in the spare regions, and a dimension A2 along the Y direction of the remaining peripheral circuit that is not placed in the spare regions shown in FIG. 4A is less than a dimension A1 along the Y direction of the respective peripheral circuit in FIG. 3A. The entire peripheral circuit in FIG. 4B is placed in the spare regions, i.e., the entire peripheral circuit in FIG. 4B is disposed below the memory cell array. It is to be noted that in some other examples, positions of the memory block, the SA and WLD corresponding to the memory block, and the peripheral circuit at spare positions may be interchanged vertically. The following illustration is performed only with an example in which the SA, the WLD, and the peripheral circuit at the spare positions are located below the memory block.

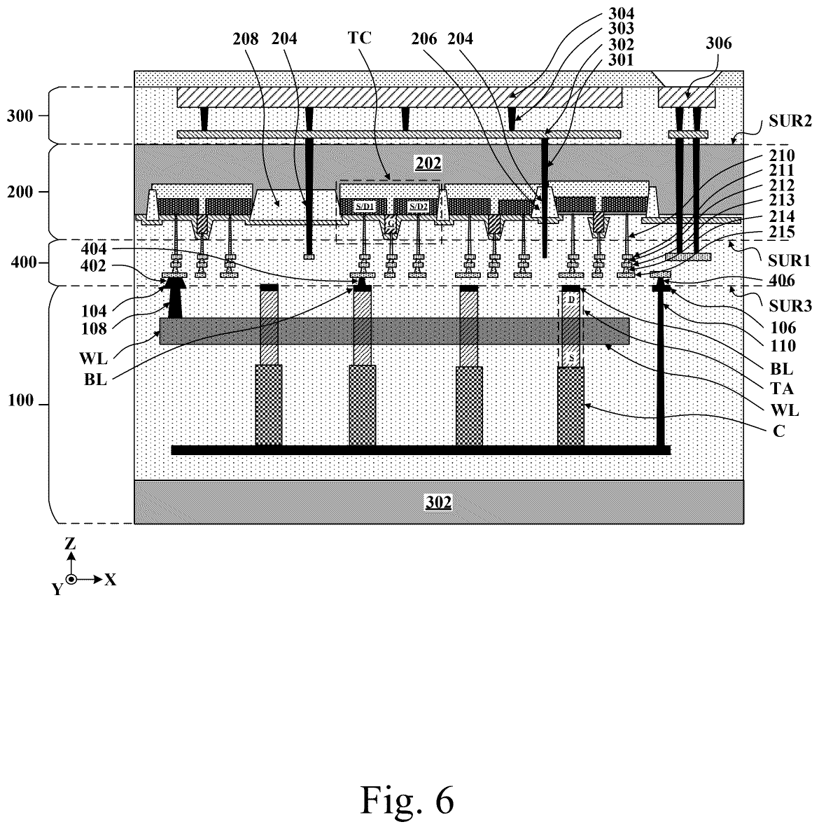

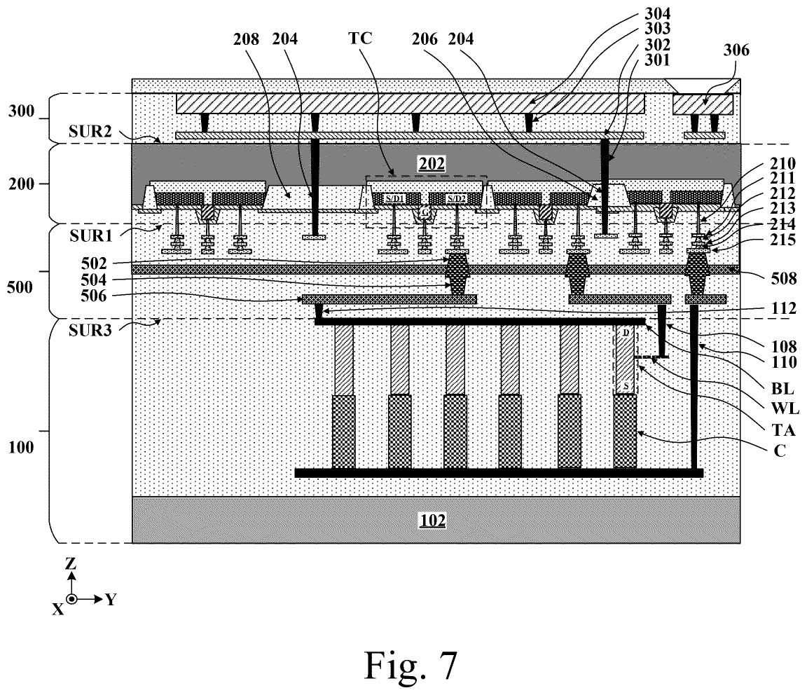

In FIG. 5A, which can be understood in contrast to FIG. 3C, a plurality of SAs and WLDs and part of the peripheral circuit PC are disposed in an array corresponding to the plurality of memory blocks disposed in an array. It is to be noted that compared with FIG. 3C, the dimension of the first control circuit in FIG. 5A is reduced, resulting in larger spare regions below each memory block array for placing at least part of the peripheral circuit PC. FIG. 5B shows a perspective view of the back-side wiring (which may be understood as a third-layer metal layer 302 in FIG. 6 and FIG. 7) of the second semiconductor structure using dashed lines, and FIG. 5B shows a Through-Silicon Contact (TSC) (which may be understood as a connection structure 204 in FIG. 6 and FIG. 7) using a solid dot. It is to be noted that the back-side wiring and relationships of the position and number of through-silicon contacts in FIG. 5B are for example purposes only and are not for limiting wiring or relationships of the position and number of through-silicon contacts in the memory device in the present application.

With reference to FIG. 5B, the back-side wiring is connected to at least part of the peripheral circuit via the through-silicon contacts, that is, the at least part of the peripheral circuit in the spare regions is connected using the back-side wiring and the through-silicon contacts, and the wiring does not conflict with the front-side wiring of the first control circuit located on the front side of the second semiconductor structure.

With reference to FIG. 5B, in some examples, a line way of the metal interconnection line in the back-side wiring of the second semiconductor structure may be configured to lay out a power supply bus. Since the power supply bus is close to the wiring of the peripheral circuit, a power supply has a very low voltage drop and high utilization. Meanwhile, a metal layer used for interconnection of the peripheral circuit on the back side of the second semiconductor structure and a metal layer used for a layout of the power supply bus can share a part of the metal layer so that a total number of metal layers on the front side and the back side can be reduced, thereby saving process costs.

In a first aspect, examples of the present application provide a memory device. With reference to FIG. 6 and FIG. 7, the memory device comprises: a first semiconductor structure comprising a memory cell array; a second semiconductor structure comprising at least a plurality of first control circuits and at least part of a peripheral circuit distributed in a gap of the plurality of first control circuits, wherein the first semiconductor structure and the second semiconductor structure are disposed as being stacked and connected; a first interconnection layer on a side of the second semiconductor structure away from the first semiconductor structure; and a plurality of connection structures, each connection structure penetrating through a portion of the second semiconductor structure, with one end being connected with the at least part of the peripheral circuit in the gap, and the other end being connected with the first interconnection layer.

Here and hereafter, the first direction also may be understood as a direction in which a word line (WL) extends, which is denoted as the X direction in the drawings; the second direction also may be understood as a direction in which a bit line (BL) extends, which is denoted as the Y direction in the drawings; and the third direction may be understood as a stacking direction of the first semiconductor structure and the second semiconductor structure, which is denoted as the Z direction in the drawings.

It is to be noted that a cross section shown in FIG. 6 is a cross section of one memory device that is formed in the direction in which the word line extends—the stacking direction of the first semiconductor structure and the second semiconductor structure, which is denoted as an X-Z cross section in the drawings; a cross section shown in FIG. 7 is a cross-section of another memory device that is formed in the direction in which the bit line extends—the stacking direction of the first semiconductor structure and the second semiconductor structure, which is denoted as a Y-Z cross section in the drawings.

It is to be noted that the components/circuits/devices etc. labeled with same labels in circuits of FIG. 6 and FIG. 7 may be understood as same or similar components/circuits/devices.

The first semiconductor structure 100 may comprise the memory cell array. Each memory cell in the memory cell array may be understood with reference to the above description of the memory cell in FIG. 1. A capacitor C may be formed in accordance with a planar configuration, a laminated configuration, or a trench configuration, depending on a manufacturing method. The capacitor C may be coupled to a first doped region (e.g., a source region S) of an array transistor TA for charging or discharging through the first doped region. The word line WL may be coupled to a gate of the array transistor TA to turn on or turn off the array transistor TA. The bit line BL may be coupled to a second doped region (e.g., a drain region D) of the array transistor TA and acts as a path for charging or discharging the capacitor C.

The second semiconductor structure 200 may comprise the first control circuit and at least part of the peripheral circuit. The first control circuit and the peripheral circuit may include any suitable analog, digital, and hybrid signal circuits for facilitating operations of the memory cell array by applying and sensing at least one of voltage signals or current signals to and from each target memory cell via the bit line and the word line. The first control circuit and the peripheral circuit may include various types of circuits formed using a MOS technology. The first control circuit and at least part of the peripheral circuit may each comprise a plurality of peripheral transistors TC to form a control circuit configured to perform operations on the memory cell array (e.g., writing or reading a memory cell of the memory cell array).

As described above, the peripheral circuit is a control circuit corresponding to all the memory banks, that is, all the memory banks share the peripheral circuit. The peripheral circuit may include, but is not limited to, a command buffer, a command decoder, an address buffer, a data buffer, and a mode register, etc. The first control circuit is a control circuit corresponding to the memory block, such as the SA and WLD. That is, each memory block corresponds to a set of SA and WLD.

The SA may be configured to sense a low power signal from the bit line BL that represents a data bit (one or zero) stored in the DRAM memory cell, and amplifies a small voltage swing to a recognizable logic level, so that data can be correctly interpreted by a logic unit outside the DRAM memory device. The WLD may be configured to apply a respective drive voltage to a word line of a selected/deselected memory block.

In some examples, the second semiconductor structure 200 comprises a first substrate 202 and a peripheral transistor TC located on a front side of the second substrate. In some examples, the first substrate 202 may include a silicon (Si), germanium (Ge), silicon germanium (SiGe) substrate, etc., and the first substrate 202 may also be silicon on insulator (SOI) or germanium on insulator (GOI). In some examples, the first substrate 202 may be doped with some impurity ions as desired, wherein the impurity ions may be N-type impurity ions or P-type impurity ions, and the doping includes well region doping and source-drain region doping. In some examples, the peripheral transistor TC may comprise an NMOS transistor formed in a P-well and a PMOS transistor formed in an N-well. The plurality of peripheral transistors TC are interconnected by the metal interconnection layer to obtain the first control circuit and at least part of the peripheral circuit.

In some examples, the front-side metal interconnection layer may be a metal interconnection layer on a surface (i.e., a first surface SUR1 (or referred to as a front side) close to the second semiconductor structure 200) of the first substrate 202 having the peripheral transistor TC, and the metal interconnection layer comprises a contact and a metal interconnection line. In some examples, the front-side interconnection layer comprises a multilayer metal layer and a plurality of contacts that are stacked alternately and interconnected. In some examples, the front-side metal interconnection layer has three stacking layers, comprising a zeroth-layer contact 210, a zeroth-layer metal layer 211, a first-layer contact 212, a first-layer metal layer 213, a second-layer contact 214, and a second-layer metal layer 215 that are stacked sequentially, wherein the multilayer metal layer comprises the zeroth-layer metal layer 211, the first-layer metal layer 213, and the second-layer metal layer 215, and the plurality of contacts comprises the zeroth-layer contact 210, the first-layer contact 212, and the second-layer contact 214. The zeroth-layer contact 210 extends and is coupled to a first source/drain S/D1, a second source/drain S/D2 of the peripheral transistor TC, or extends to a gate G of the peripheral transistor TC. Here and hereafter, materials of the contacts and the metal interconnection line includes, but is not limited to, tungsten, cobalt, nickel, copper, aluminum, polysilicon, doped silicon, silicide, nitride, or any combination thereof.

The first interconnection layer 300 is located on the side of the second semiconductor structure 200 away from the first semiconductor structure 100. In an example, the first interconnection layer 300 may be understood as a back-side metal interconnection layer, which may be a metal interconnection layer formed on a second surface SUR2 (or referred to as a back side) of the second semiconductor structure 200, wherein the metal interconnection layer comprises contacts and a metal interconnection line.

In some examples, the back-side interconnection layer comprises a multilayer metal layer and a plurality of contacts that are stacked alternately and interconnected. In some examples, the back-side metal interconnection layer has two stacking layers, comprising a third-layer contact 301, a third-layer metal layer 302, a fourth-layer contact 303, and a fourth-layer metal layer 304 that are stacked sequentially, wherein the multilayer metal layer comprises the third-layer metal layer 302 and the third-layer metal layer 304, and the plurality of contacts comprises the third-layer contact 301 and the fourth-layer contact 303. The third-layer contact 301 (which may be understood as the connection structure 204) extends and is coupled to the front-side metal interconnection layer, for example, third-layer contact 301 extends and is coupled to the zeroth-layer metal layer 211. In some examples, a material of the third-layer metal layer 302 is the same as or different from a material of the fourth-layer metal layer 304. In some examples, the material of the fourth-layer metal layer 302 includes aluminum or an aluminum alloy, and the material of the third-layer metal layer 302 includes copper or a copper alloy.

The connection structure 204 penetrates through the portion of the second semiconductor structure 200, with one end being connected with the at least part of the peripheral circuit in the gap, and the other end being connected with the first interconnection layer 300. In an example, the connection structure 204 penetrates through the first substrate 202, with one end extending to the front-side metal interconnection layer to be connected with the at least part of the peripheral circuit in the second semiconductor structure 200, and the other end extending to the back-side metal interconnection layer to be connected with the first interconnection layer 300, e.g., the connection structure 204 penetrates through two ends of the first substrate 202 and extends to the third-layer metal layer 302 and the zeroth-layer metal layer 211 respectively.

The gap may be understood as a first insulation structure 206 that spaces apart a plurality of active regions in the first substrate 202, or may be understood as a second insulation structure 208 that spaces apart a plurality of well regions (P-wells/N-wells) in the first substrate 202. The first insulation structure 206 and the second insulation structure 208 in the first substrate 202 may be obtained through a shallow trench isolation (STI) process. A material of the first insulation structure 206 and the second insulation structure 208 includes, but is not limited to, silicon oxide, silicon nitride, silicon oxynitride, or any combination thereof.

Details of the interconnection between layers of the first semiconductor structure 100 and the second semiconductor structure 200 may be referred to descriptions below.

In the examples of the present application, the first semiconductor structure and the second semiconductor structure are disposed as being stacked, so that the storage density of the memory device can be increased greatly. Through the wiring on the back side of the second semiconductor structure and connection to the at least part of the peripheral circuit via the connection structures, the at least part of the peripheral circuit can be laid out below the memory block of the memory cell array dispersedly, directly reducing the area occupied by the peripheral circuit in the second semiconductor structure. The back-side wiring of the second semiconductor structure may achieve interconnection between the at least part of the peripheral circuit laid out dispersedly, without conflicting with the connection of the front-side wiring of the second semiconductor structure.

With reference to FIG. 6, in some examples, the memory device further comprises a second interconnection layer located between the first semiconductor structure and the second semiconductor structure, wherein the first semiconductor structure and the second semiconductor structure are connected by the second interconnection layer. The second interconnection layer 400 may be a metal interconnection layer formed on the first surface SUR1 (or referred to as the front side) of the second semiconductor structure 200, and on a third surface SUR3 of the first semiconductor structure 100 (the third surface SUR3 may be understood as a surface of the first semiconductor structure 100 close to the first surface SUR1). The second interconnection layer 400 may comprise one or more interconnection layers, e.g., comprise the aforementioned zeroth-layer contact 210, the zeroth-layer metal layer 211, the first-layer contact 212, the first-layer metal layer 213, the second-layer contact 214, and the second-layer metal layer 215 that are stacked sequentially. The second interconnection layer 400 may further comprise a word line contact 402, a bit line contact 404, etc. A material of the word line contact 402 and the bit line contact 404 includes, but is not limited to, tungsten, cobalt, nickel, copper, aluminum, polysilicon, doped silicon, silicide, nitride, or any combination thereof. In some examples, the second interconnection layer further comprises a capacitor common electrode contact 406. A material of the capacitor common electrode contact 406 includes, but is not limited to, tungsten, cobalt, nickel, copper, aluminum, polysilicon, doped silicon, silicide, nitride, or any combination thereof.

It is to be noted that in the example illustrated in FIG. 6, the first semiconductor structure and the second semiconductor structure are connected only by the second interconnection layer therebetween. A third substrate 302 is a substrate functioning as a carrier, rather than a substrate used as a growth substrate, and the third substrate 302 may be removed selectively. That is, the first semiconductor structure and the second semiconductor structure in the example shown in FIG. 6 are both grown on the basis of the first substrate 202, so that the use of the growth substrate can be reduced to save the costs.

With reference to FIG. 7, in some examples, the memory device further comprises a third interconnection layer, a first bonding layer, a second bonding layer, and a fourth interconnection layer that are disposed as being stacked between the first semiconductor structure and the second semiconductor structure, wherein the first semiconductor structure and the second semiconductor structure are connected by the third interconnection layer, the first bonding layer, the second bonding layer, and the fourth interconnection layer.

Here and hereafter, the third interconnection layer, the first bonding layer, the second bonding layer, and the fourth interconnection layer may be referred to as a bonding interconnection structure 500. The bonding interconnection structure 500 comprises a contact and a metal interconnection line.

The third interconnection layer and the first bonding layer may be a metal interconnection layer (comprising a contact and a metal interconnection line) formed on the first surface SUR1 (or referred to as the front side) of the second semiconductor structure 200. The third interconnection layer may comprise one or more interconnection layers, e.g., comprise the aforementioned zeroth-layer contact 210, the zeroth-layer metal layer 211, the first-layer contact 212, the first-layer metal layer 213, the second-layer contact 214, and the second-layer metal layer 215 that are stacked sequentially. The first bonding layer may comprise a first bonding contact 502. The fourth interconnection layer and the second bonding layer may be a metal interconnection layer (comprising a contact and a metal interconnection line) formed on the third surface SUR3 of the first semiconductor structure 100. The fourth interconnection layer may comprise one or more interconnection layers, e.g., comprise a fifth-layer metal layer 506. The second bonding layer may comprise a second bonding contact 504. The second semiconductor structure 200 having the first bonding contact 502 and the first semiconductor structure 100 having the second bonding contact 504 may form the bonding interconnection structure 500 having a bonding interface 508 through a hybrid bonding process etc. The first bonding contact 502 and the second bonding contact 504 contact and are electrically connected with each other.

It is to be noted that in the example illustrated in FIG. 7, the first semiconductor structure and the second semiconductor structure are connected by bonding. The first substrate 202 is used as a growth substrate for the second semiconductor structure 200, and the second substrate 102 is used as a growth substrate for the first semiconductor structure 100. That is, in the example illustrated in FIG. 7, the first semiconductor structure and the second semiconductor are grown and fabricated respectively using different substrates. As such, the problem of mutual constraints between a process of the memory cell array and a process of the peripheral circuit can be solved, thereby shortening a development cycle of the memory device.

With reference to FIG. 5B, in some examples, the memory cell array comprises a plurality of memory banks, each memory bank comprising a plurality of memory blocks; one first control circuit is connected with one of the memory blocks, and the peripheral circuit is connected with all the memory banks; and the at least part of the peripheral circuit comprises a plurality of first portions and one second portion. A boundary of a region for disposing one of the first portions and the first control circuit correspondingly connected with one respective memory block overlaps a boundary of a region for disposing the respective memory block; and a boundary of a region for disposing a second portion overlaps a boundary of the gap between adjacent ones of the memory blocks. At least one of the second portion or the plurality of first portions is connected with the first interconnection layer by the plurality of connection structures.

In some examples, the memory cell array may comprise a plurality of memory banks, such as 16 memory banks, and the number of the memory banks may also be less than or more than 16. Each memory bank may comprise a plurality of memory blocks, such as 16 memory blocks, and the number of the memory blocks may also be less than or more than 16.

In some examples, the spare regions SZ may comprise a first spare region SZ1 in a projection region below the memory block excluding a layout of the first control circuit, and a second spare region SZ2 that may be located in a projection region below the gap between adjacent ones of the memory blocks. The number of first spare regions SZ1 is the same as the number of the memory block included in the memory cell array.

In an example, the at least part of the peripheral circuit PC comprises a plurality of first portions PC1 (two first portions PC1 are shown in FIG. 5B) in the first spare regions SZ1 and one second portion PC2 in the second spare region SZ2. As shown in FIG. 5B, the two first portions PC1 are located below the memory block and spaced apart, and the one second portion PC2 is located as a whole below a position between adjacent ones of the memory blocks. The two first portions PC1 and the one second portion PC2 are connected to the third-layer metal layer 302 of the first interconnection layer by the plurality of connection structures 204.

With reference to FIG. 6 and FIG. 7, in some examples, the first control circuits comprise a sensing amplifier and a word line driver, wherein the sensing amplifier is connected with the bit line in the memory block, and the word line driver is connected with the word line in the memory block.

With reference to FIG. 6, in some examples, the first semiconductor structure 100 may comprise the memory cell array, and the first control circuits of the second semiconductor structure 200 may comprise the word line driver and the sensing amplifier, wherein the word line WL of the memory cell array may be connected with the word line driver via the word line contact 402, and the bit line BL of the memory cell array may be connected with the sensing amplifier via the bit line contact 404. In some examples, the word line WL may be connected with the word line contact 402 via a word line connection structure 108 and a word line landing pad 104. In addition, the capacitor C may be connected with the capacitor common electrode contact 406 via a capacitor connection structure 110 and a capacitor landing pad 106.

With reference to FIG. 7, in some examples, the first semiconductor structure 100 may comprise the memory cell array, and the first control circuits of the second semiconductor structure 200 may comprise the word line driver and the sensing amplifier, wherein the word line WL of the memory cell array may be connected with the word line driver via the bonding interconnection structure 500, and the bit line BL of the memory cell array may be connected with the sensing amplifier via the bonding interconnection structure 500. In some examples, the word line WL, the bit line BL, and the capacitor C of the memory cell array in the first semiconductor structure 100 may be connected to the fifth-layer metal layer 506 of the bonding interconnection structure 500 respectively via the word line connection structure 108, the bit line connection structure 112, and the capacitor connection structure 110, be connected to a plurality of second bonding contacts 504 and a plurality of first bonding contacts 502 of the bonding interconnection structure 500 via the fifth-layer metal layer 506 of the bonding interconnection structure 500, and be connected to the word line driver and the sensing amplifier in the second semiconductor structure 200 respectively via the plurality of first bonding contacts 502.

In some examples, at least one of the word line connection structure 108 or the bit line connection structure 112 may be located directly below the memory block.

With reference to FIG. 5A, in some examples, the sensing amplifier connected with the memory block is disposed in a first region and a second region; and the word line driver connected with the memory block is disposed in a third region and a fourth region. The first region and the second region both extend along a first direction and are disposed as being staggered along a second direction, the third region and the fourth region both extend along the second direction and are disposed as being staggered along the first direction, the first direction is perpendicular to the direction in which the bit line extends, and the second direction is perpendicular to the direction in which the word line extends.

Here, the first region and the second region are used for placing the sensing amplifier. Considering that the sensing amplifier is connected with the bit line and the bit line extends along the second direction and arranged along the first direction, in order to facilitate wiring of the bit lines and the sensing amplifier, e.g., the connection structure between the bit line and the sensing amplifier extending along the Z direction, the first region and the second region both extend along the first direction. The third region and the fourth region are used for placing the word line driver. Considering that the word line driver is connected with the word line and the word line extends along the first direction and are arranged along the second direction, in order to facilitate wiring of the word line and the word line driver, the third region and the fourth region both extend along the second direction. It is to be noted that positions of the SA and WLD in corresponding regions (projection regions) below the memory block can be adjusted according to actual demands, and a position layout of them mainly considers the convenience of connection with the word line and the bit line in the memory block, without excessively fragmental division of the corresponding regions below the memory block.

It may be understood that disposing SA and WLD corresponding to the memory block in the corresponding regions (projection regions) directly below the memory block may reduce a total length of the wiring from the bit line to the sensing amplifier, thereby reducing a coupling effect and increasing a sensing window.

In some other examples, in a corresponding region below the memory block block4, the first region and the second region are disposed diagonally and adjacent to each other, and the third region and the fourth region are disposed diagonally and isolated from each other. The sensing amplifier, also referred to as sensing amplifier SA, comprises a first sensing portion SA1 and a second sensing portion SA2 disposed in the first region and the second region respectively. The word line driver, also referred to as word line driver WLD, comprises a first driving portion WLD1 and a second driving portion WLD2 disposed in the third region and the fourth region respectively. In some examples, a sum of dimensions of boundaries of the regions for disposing the first sensing portion SA1 and the second sensing portion SA2 along the first direction is less than or equal to a dimension of a boundary of a region for disposing the memory block block4 along the first direction (a less-than case is illustrated in FIG. 5A); a sum of dimensions of boundaries of the regions for disposing the first driving portion WLD1 and the second driving portion WLD2 along the second direction is less than or equal to a dimension of a boundary of the region for disposing the memory block block4 along the second direction (an equal-to case is illustrated in FIG. 5A).

In some examples, a boundary of the first region contacts a boundary of the third region, and a boundary of the second region contacts a boundary of the fourth region; a sum of dimensions of the boundary of the first region and the boundary of the third region along the first direction is a first dimension, a dimension of a boundary of the region for disposing the memory block along the first direction is a second dimension, and the first dimension is less than the second dimension.

Here, the first dimension is less than the second dimension, allowing for more spare regions for placing the peripheral circuit.

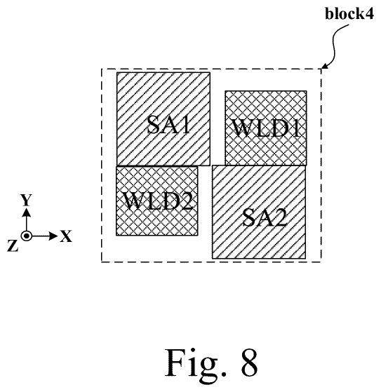

With reference to FIG. 8, in some other examples, in a corresponding region below the memory block block4, the first region and the second region are disposed diagonally and adjacent to each other, and the third region and the fourth region are disposed diagonally and isolated from each other. The sensing amplifier, also referred to as sensing amplifier SA, comprises a first sensing portion SA1 and a second sensing portion SA2 disposed in the first region and the second region respectively, wherein a sum of dimensions of the first sensing portion SA1 and the second sensing portion SA2 along the first direction is less than a dimensions of the memory block block4 along the first direction. The word line driver, also referred to as word line driver WLD, comprises a first driving portion WLD1 and a second driving portion WLD2 disposed in the third region and the fourth region respectively, wherein a sum of dimensions of the first driving portion WLD1 and the second driving portion WLD2 along the second direction is less than a dimension of the memory block block4 along the second direction.

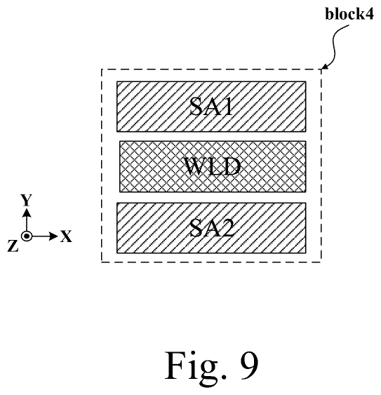

With reference to FIG. 9, in some examples, in a corresponding region below the memory block block4, the sensing amplifier SA and the word line driver WLD are both disposed as extending along the first direction, wherein the sensing amplifier SA comprises two portions (the first sensing portion SA1 and the second sensing portion SA2) spaced apart along the second direction, and the word line driver WLD is located between the first sensing portion SA1 and the second sensing portion SA2 as a whole. A dimension of a boundary of a region for disposing the first sensing portion SA1 and the second sensing portion SA2 along the first direction is less than the dimension of the boundary of the region for disposing the memory block block4 along the first direction. A dimension of a boundary of a region for disposing the word line driver WLD along the second direction is less than the dimension of the memory block block4 along the second direction. Furthermore, a dimension of a boundary of the region for disposing the word line driver WLD along the first direction is less than the dimension of the boundary of the region for disposing the memory block block4 along the first direction.

With reference to FIG. 6 and FIG. 7, in some examples, the first semiconductor structure 100 further comprises a first contact connected with the word line WL and a second contact connected with the bit line BL, wherein the first contact and the second contact are both disposed on a side close to the second semiconductor structure; the second semiconductor structure 200 further comprises a third contact connected with the sensing amplifier and a fourth contact connected with the word line driver, wherein the third contact and the fourth contact are both disposed on a side close to the first semiconductor structure. The second contact and the third contact, as well as the first contact and the fourth contact, are connected at least by the interconnection layer between the first semiconductor structure and the second semiconductor structure.

Here, the first contact may be understood as the word line connection structure 108 and the word line landing pad 104 in FIG. 6, the second contact may be understood as the bit line contact 404 in FIG. 6, the third contact may be understood as a portion of the front-side metal interconnection layer in FIG. 6 that is connected to the sensing amplifier, and the fourth contact may be understood as a portion of the front-side metal interconnection layer in FIG. 6 that is connected to the word line driver. The second contact and the third contact, as well as the first contact and the fourth contact, are connected at least by the second interconnection layer 400 between the first semiconductor structure and the second semiconductor structure. Here, the first contact may be understood as the word line connection structure 108 in FIG. 7, the second contact may be understood as the bit line connection structure 112 in FIG. 7, the third contact may be understood as a portion of the front-side metal interconnection layer in FIG. 7 that is connected to the sensing amplifier, and the fourth contact may be understood as a portion of the front-side metal interconnection layer in FIG. 7 that is connected to the word line driver. The second contact and the third contact, as well as the first contact and the fourth contact, are connected by the bonding interconnection structure 500 between the first semiconductor structure and the second semiconductor structure. In some examples, at least one of the first contact or the second contact may be located on an edge of the memory cell array or may be located directly below the memory cell array.

In some examples, the first semiconductor structure 100 further comprises a fifth contact connected with the capacitor C, wherein the fifth contact is disposed on a side close to the second semiconductor structure; the second semiconductor structure 200 further comprises a sixth contact connected with the common electrode, wherein the sixth contact is disposed on a side close to the first semiconductor structure. The fifth contact and the sixth contact are connected by the interconnection layer between the first semiconductor structure and the second semiconductor structure. In some examples, the fifth contact may be located on an edge of the memory cell array.

With reference to FIG. 6 and FIG. 7 in conjunction with reference to FIG. 5B, in some examples, the second semiconductor structure comprises a plurality of active regions spaced apart by the isolation regions, and the connection structures are disposed at boundaries of the active regions and in the isolation regions.

In some examples, the first substrate 202 of the second semiconductor structure 200 comprises the first insulation structure 206 that spaces apart the plurality of active regions, and the connection structure 204 may be disposed in the first insulation structure 206; and/or, the first substrate 202 of the second semiconductor structure 200 further comprises the second insulation structure 208 that spaces apart the plurality of well regions (P-wells/N-wells), and the connection structure 204 may be disposed in the second insulation structure 208. The material and position of the first insulation structure 206 and the second insulation structure 208 are described above, which are no longer repeated here.

Here, laying out the connection structures 204 at the boundaries of the active regions and in the isolation regions may prevent the connection structures penetrating through the first substrate from destroying a partial structure of the first control circuit or at least part of the peripheral circuit that is located in the first substrate.

With reference to FIG. 6 and FIG. 7 in some examples, the memory device further comprises a power supply line disposed in the first interconnection layer.

In some examples, a portion (e.g., the fourth-layer metal layer 304 shown in FIG. 6 and FIG. 7) of the metal interconnection line of the first interconnection layer 300 serves as the power supply line, and the power supply line is connected with a wiring layer corresponding to the at least part of the peripheral circuit via a contact (e.g., the fourth-layer contact 303 shown in FIG. 6 and FIG. 7). A portion (e.g., the third-layer metal layer 302 shown in FIG. 6 and FIG. 7) of the metal interconnection line of the first interconnection layer 300 serves as the wiring layer of the peripheral circuit, and the wiring of the peripheral circuit is connected with the at least part of the peripheral circuit PC via a contact (e.g., the connection structure 204 shown in FIG. 6 and FIG. 7).

It is to be noted that in some other examples, positions for the power supply line and the wiring layer of the peripheral circuit may be interchanged up and down. In some other examples, positions for the power supply line and the wiring layer of the peripheral circuit may be distributed at different positions in the same metal layer. To sum up, the examples of the present application do not limit a positional relationship between them.

It may be also understood that supplying power on the back side of the second semiconductor structure allows for smaller distances from a power supply to the peripheral circuit and the first circuit, leading to a lower voltage drop in the wiring and thus higher utilization of the power supply. Meanwhile, a metal layer used for interconnection of the peripheral circuit on the back side of the second semiconductor structure and a metal layer used for a layout of the power supply bus can share a part of the metal layer so that a total number of metal layers on the front side and the back side can be reduced, thereby saving the process costs and reducing a dimension occupied by the metal layers.

In some examples, the second semiconductor structure further comprises a plurality of second control circuits each of which is connected with one memory bank. The second control circuits are distributed in the gap of the plurality of first control circuits, and the second control circuits comprise a row decoding circuit and a column decoding circuit.

Here, the second control circuit is a control circuit corresponding to the memory bank, such as the column decoding circuit and row decoding circuit mentioned above. Each memory bank corresponds to a set of column decoding circuit and row decoding circuit. In addition to placing the peripheral circuit in the spare regions mentioned above, the column decoding circuit and the row decoding circuit are also placed at corresponding positions below the memory bank.

In some examples, a boundary of a region for disposing a second control circuit overlaps a boundary of the gap between adjacent ones of the memory banks.

Here, considering the convenience of wiring, a set of column decoding circuit and row decoding circuit corresponding to each memory bank is disposed next to the corresponding positions below the respective memory bank. For example, the second control circuit is disposed at a corresponding position below the gap between adjacent ones of the memory banks, so that the boundary of the region for disposing the second control circuit overlaps the boundary of the gap between adjacent ones of the memory banks.

As such, an additional area occupied by the second control circuit can be reduced, thereby further increasing the storage density of the memory device.

With reference to FIG. 6 and FIG. 7 in some examples, the memory device further comprises a pad, which is located on a side of the first interconnection layer away from the second semiconductor structure and is electrically connected with the first interconnection layer.

Here, the pad 306 may be located on the first interconnection layer and be electrically connected with the first interconnection layer. In an example, the pad 306 may be used as a lead-out pad for the memory device, so as to electrically connect the memory device with an external device via the lead-out pad. A material of the pad 306 may be understood with reference to the material of the fourth-layer metal layer 304 mentioned above. For example, the material of the pad 306 include a metal material such as aluminum or aluminum alloy which is easy to be patterned directly through lithography, and may also include a metal material such as copper or copper alloy which has good electrical conductivity.

With reference to FIG. 6 and FIG. 7, in some examples, the memory cell array comprises: a plurality of word lines WL extending along the first direction; a plurality of bit lines BL extending along the second direction; a plurality of semiconductor pillars arranged in an array; and a storage structure corresponding to each semiconductor pillar, the semiconductor pillar and the corresponding storage structure being disposed as being stacked, wherein the semiconductor pillar extends along the third direction and has a first end and a second end disposed oppositely in the third direction, and wherein the first end is connected with the bit line, and the second end is connected with the storage structure. The word line is coupled with at least one side of the semiconductor pillar. The third direction is perpendicular to both the first direction and the second direction.

Here, the semiconductor pillar may be understood as a channel structure of the array transistor TA in FIG. 6 or FIG. 7. The storage structure may be understood as the capacitor C in FIG. 6 or FIG. 7.

In the examples of the present application, the semiconductor pillar extends along the third direction, that is, the channel structure of the array transistor extends along the third direction. The array transistor acts as a vertical transistor, which is favorable to reduction of a dimension of the array transistor. The array transistor and the storage structure are disposed as being stacked along the third direction. A unit memory cell area of the memory cell array may be 4 cell array areas (i.e., 4F²), which can improve the level of integration of the memory device.

With reference to FIG. 6 and FIG. 7, in some examples, the storage structure comprises the capacitor, and the capacitor C comprises a cup-shaped capacitor, a cylindrical capacitor, or a pillar-shaped capacitor. In an example, the cup-shaped capacitor, the cylindrical capacitor, and the pillar-shaped capacitor each comprise a bottom electrode, a top electrode, and a dielectric layer between the bottom electrode and the top electrode. It is to be noted that the bottom electrode of one capacitor is connected with the source of the array transistor, and all top electrodes of capacitors are connected with the common electrode for grounding. The capacitor is configured to store written data.

It is to be noted that when areas of bottom electrodes of the cup-shaped capacitor, the cylindrical capacitor, and the pillar-shaped capacitor are equal, an area of a top electrode of the cylindrical capacitor is maximum, and areas of top electrodes of the cup-shaped capacitor and the pillar-shaped shaper are smaller. Accordingly, in some examples, the cylindrical capacitor may be used as a memory cell of the memory, which is favorable to the improvement of the level of integration of the memory device.

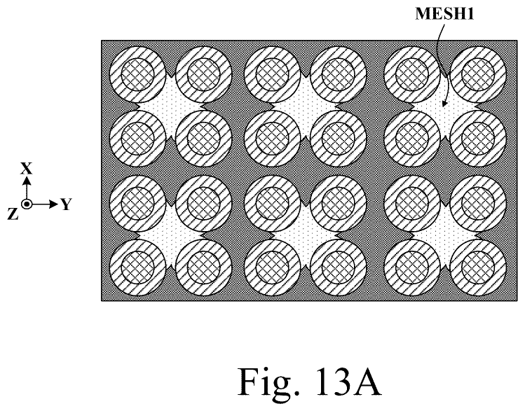

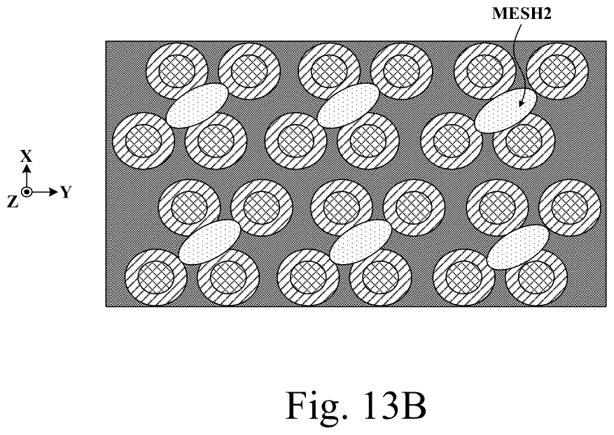

In some examples, the plurality of storage structures are arranged in a square or hexagon. In an example, with reference to FIG. 13A, in the X-Y top view plane, an array layout of the plurality of storage structures may present a square arrangement, and the gap between the four storage structures arranged in the square is a first gap MESH1. In an example, with reference to FIG. 13B, in the X-Y top view plane, an array layout of the plurality of storage structures may present a hexagonal arrangement, and the gap between the four storage structures arranged in the hexagon is a second gap MESH2. In practical applications, the plurality of storage structures may also present other array layouts, in addition to the square arrangement and the hexagonal arrangement. Compared with the square arrangement of the plurality of storage structures, the hexagonal arrangement of the plurality of storage structures has a higher arrangement density, for example, the second gap MESH2 is smaller than the first gap MESH1, which is favorable to the improvement of the level of integration of the memory device.

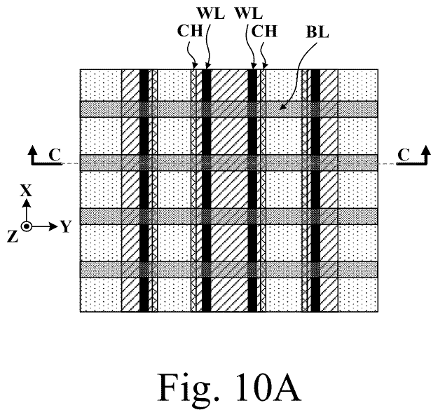

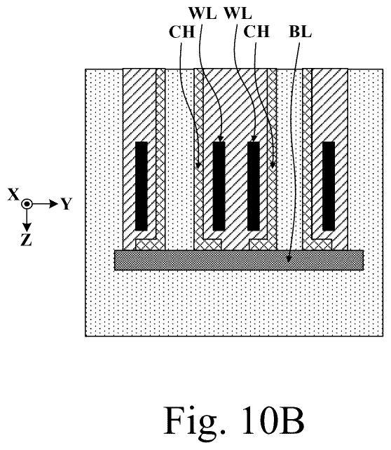

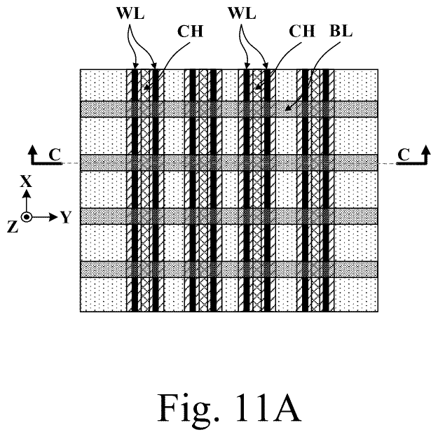

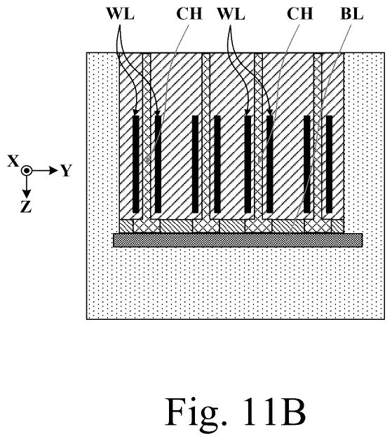

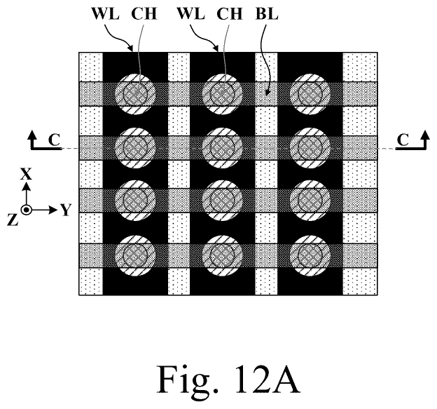

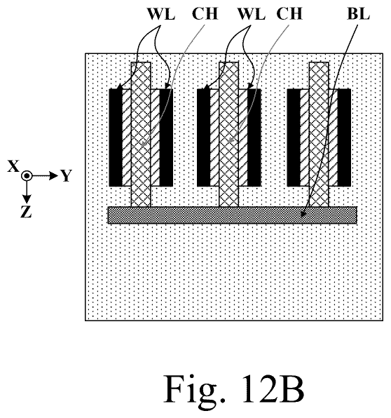

In some examples, with reference to FIG. 10A and FIG. 10B, the word line WL is coupled with one side surface of the semiconductor pillar CH, so as to form a single-side gate structure. Alternatively, with reference to FIG. 11A and FIG. 11B, the word line WL is coupled with two side surfaces of the semiconductor pillar CH that are disposed oppositely, so as to form a double-side gate structure. Alternatively, with reference to FIG. 12A and FIG. 12B, the word line WL is coupled with each side surface of the semiconductor pillar CH, so as to form a gate-all-around structure.

In some examples, a material of the semiconductor pillar CH may include at least one of indium gallium zinc oxide, indium zinc oxide, gallium zinc oxide, indium gallium oxide, zinc oxide, indium oxide, and gallium oxide. In some examples, the material of the semiconductor pillar CH includes indium gallium zinc oxide.

It may be understood that the indium gallium zinc oxide is characterized by high mobility, good uniformity, low power consumption, and low noise, and a transistor channel formed by the semiconductor pillar CH including the indium gallium zinc oxide has both a high field effect mobility and a high threshold voltage, leading to better performance. In addition, the indium gallium zinc oxide may be prepared directly through processes such as deposition, and is easy to process.

In a second aspect, the examples of the present application provide another memory device. With reference to FIG. 6, the memory device comprises: a first semiconductor structure 100 comprising a memory cell array; a second semiconductor structure 200 comprising at least a plurality of first control circuits and at least part of a peripheral circuit distributed in a gap of the plurality of first control circuits; a first interconnection layer 300 on a side of the second semiconductor structure away from the first semiconductor structure; a plurality of connection structures 204, each connection structure 204 penetrating through a portion of the second semiconductor structure, with one end being connected with the at least part of the peripheral circuit in the gap, and the other end being connected with the first interconnection layer; and a second interconnection layer 400 between the first semiconductor structure 100 and the second semiconductor structure 200, which is connected with both the memory cell array and the first control circuit.

Details of a planar layout of the memory device shown in FIG. 6 may be understood with reference to FIG. 4A, FIG. 4B, FIG. 5A and FIG. 5B. In some examples, the memory cell array comprises a plurality of memory banks, each memory bank comprising a plurality of memory blocks, one first control circuit is connected with one of the memory blocks, and the peripheral circuit is coupled with all the memory banks; the at least part of the peripheral circuit comprises a plurality of first portions PC1 and one second portion PC2. A boundary of a region for disposing one of the first portions PC1 and the first control circuit connected with one respective memory block overlaps a boundary of a region for disposing the respective memory block; and a boundary of a region for disposing a second portion PC2 overlaps a boundary of the gap between adjacent ones of the memory blocks. At least one of the second portion or the plurality of first portions is connected with the first interconnection layer by the plurality of connection structures.

In some examples, the memory device further comprises a power supply line disposed in the first interconnection layer 300.

In the examples of the present application, the first semiconductor structure and the second semiconductor structure are disposed as being stacked, so that the storage density of the memory device can be increased greatly. Through the wiring on the back side of the second semiconductor structure and connection to the at least part of the peripheral circuit via the connection structures, the at least part of the peripheral circuit can be laid out below the memory block of the memory cell array dispersedly, directly reducing the area occupied by the peripheral circuit in the second semiconductor structure. The back-side wiring of the second semiconductor structure may achieve interconnection between the at least part of the peripheral circuit laid out dispersedly, without conflicting with the connection of the front-side wiring of the second semiconductor structure. Meanwhile, the first semiconductor structure and the second semiconductor structure are both grown on the same substrate, so that the use of the growth substrate can be reduced to save the costs.

In a third aspect, the examples of the present application further provide a memory device. With reference to FIG. 7, the memory device comprises: a first semiconductor structure 100 comprising a memory cell array; a second semiconductor structure 200 comprising at least a plurality of first control circuits and at least part of a peripheral circuit distributed in a gap of the plurality of first control circuits; a first interconnection layer 300 on a side of the second semiconductor structure away from the first semiconductor structure; and a third interconnection layer, a first bonding layer, a second bonding layer, and a fourth interconnection layer (the third interconnection layer, the first bonding layer, the second bonding layer, and the fourth interconnection layer may be referred to as the bonding interconnection structure 500) that are disposed as being stacked between the first semiconductor structure and the second semiconductor structure and connected with both the memory cell array and the first control circuit.

Details of a planar layout of the memory device shown in FIG. 7 may also be understood with reference to FIG. 4A, FIG. 4B, FIG. 5A and FIG. 5B. In some examples, the memory cell array comprises a plurality of memory banks, each memory bank comprising a plurality of memory blocks, one first control circuit is connected with one memory block, and the peripheral circuit is connected with all the memory banks; the at least part of the peripheral circuit comprises a plurality of first portions PC1 and one second portion PC2. A boundary of a region for disposing one first portion PC1 and the first control circuit connected with one respective memory block overlaps a boundary of a region for disposing the respective memory block; and a boundary of a region for disposing a second portion PC2 overlaps a boundary of the gap between adjacent ones of the memory blocks. At least one of the second portion or the plurality of first portions is connected with the first interconnection layer by the plurality of connection structures.

In some examples, the memory device further comprises a power supply line disposed in the first interconnection layer.

In the examples of the present application, the first semiconductor structure and the second semiconductor structure are disposed as being stacked, so that the storage density of the memory device can be increased greatly. Through the wiring on the back side of the second semiconductor structure and connection to the at least part of the peripheral circuit via the connection structures, the at least part of the peripheral circuit can be laid out below the memory block of the memory cell array dispersedly, directly reducing the area occupied by the peripheral circuit in the second semiconductor structure. The back-side wiring of the second semiconductor structure may achieve interconnection between the at least part of the peripheral circuit laid out dispersedly, without conflicting with the connection of the front-side wiring of the second semiconductor structure. Meanwhile, the first semiconductor structure and the second semiconductor structure are grown and fabricated respectively using different substrates. As such, the problem of mutual constraints between a process of the memory cell array and a process of the peripheral circuit can be solved, thereby shortening a development cycle of the memory device.

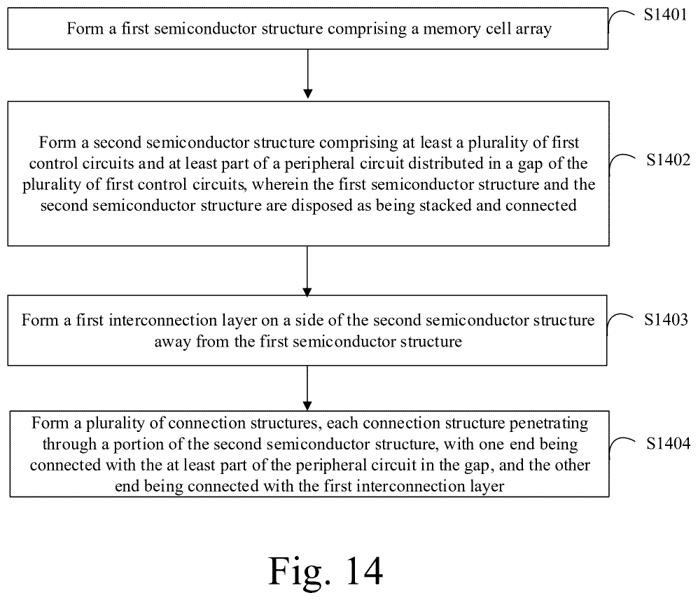

In a fourth aspect, the examples of the present application provide a manufacturing method of a memory device. With reference to FIG. 14, FIG. 14 is a flow diagram of a fabrication method of a memory device provided by examples of the present application. The method comprises:

Operation S1401: forming a first semiconductor structure comprising a memory cell array;

Operation S1402: forming a second semiconductor structure comprising at least a plurality of first control circuits and at least part of a peripheral circuit distributed in a gap of the plurality of first control circuits, wherein the first semiconductor structure and the second semiconductor structure are disposed as being stacked and connected;

Operation S1403: forming a first interconnection layer on a side of the second semiconductor structure away from the first semiconductor structure; and

Operation S1404: forming a plurality of connection structures, each connection structure penetrating through a portion of the second semiconductor structure, with one end being connected with the at least part of the peripheral circuit in the gap, and the other end being connected with the first interconnection layer.

It is to be understood that operations illustrated in FIG. 14 are not exclusive, and other operations may be also performed before, after, or between any of the illustrated operations. A sequence of the operations illustrated in FIG. 14 can be adjusted according to actual needs. As described above, there can be many different relative positions between the gate (word line) and the semiconductor pillar in the memory device, and the different relative positions correspond to different fabrication methods. In the examples of the present application, the illustrate is performed with an example in which two gates corresponding to two adjacent semiconductor bodies are disposed back-to-back (the back-to-back pattern shown in FIG. 10A and FIG. 10B).

There are a variety of methods for forming the first semiconductor structure, the second semiconductor structure, the first interconnection layer, and the connection structure, some of which are illustrated as an example in the examples of the present application. A process of forming the first semiconductor structure, the second semiconductor structure, the first interconnection layer, and the connection structure is described in detail below in conjunction with the drawings.

During execution of the operations S1401 to S1404, in some examples, forming the first semiconductor structure, the second semiconductor structure, and the first interconnection layer comprises: forming the second semiconductor structure on a first surface of a first substrate; forming a second interconnection layer on the second semiconductor structure; forming the first semiconductor structure on the second interconnection layer, wherein the first semiconductor structure and the second semiconductor structure are connected by the second interconnection layer; and forming the first interconnection layer on a second surface of the first substrate, wherein the first surface and the second surface are two surfaces disposed oppositely along a thickness direction of the first substrate.

In some examples, forming the first semiconductor structure comprises: forming a plurality of bit lines extending along a second direction; forming a plurality of semiconductor pillars on surfaces of the bit lines, each semiconductor pillar extending along the thickness direction of the first substrate; forming a plurality of word lines extending along a first direction, each word line being located on at least one side surface of the semiconductor pillar, wherein the first direction and the second direction are both perpendicular to the thickness direction of the first substrate; and forming a storage structure on a surface of each semiconductor pillar away from the bit line.

In some examples, the method further comprises: providing a third substrate; bonding the third substrate to the storage structure to form a bonding structure; flipping the bonding structure to expose the second surface of the first substrate; and removing the third substrate after forming the first interconnection layer on the second surface of the first substrate.

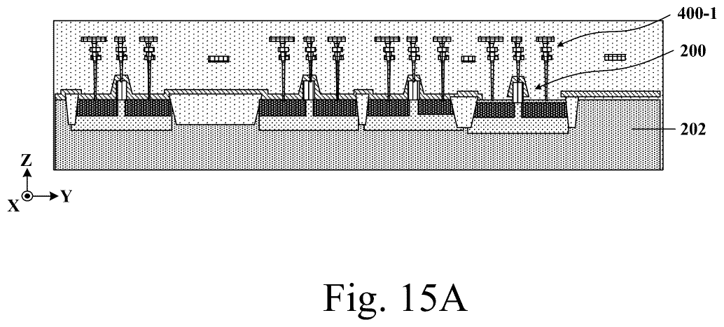

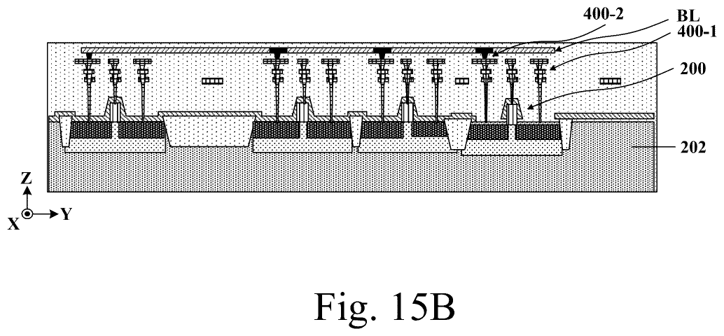

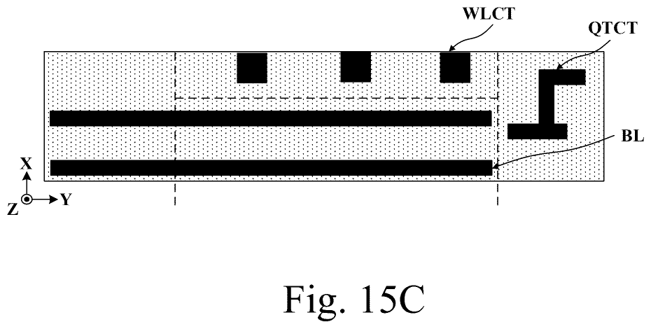

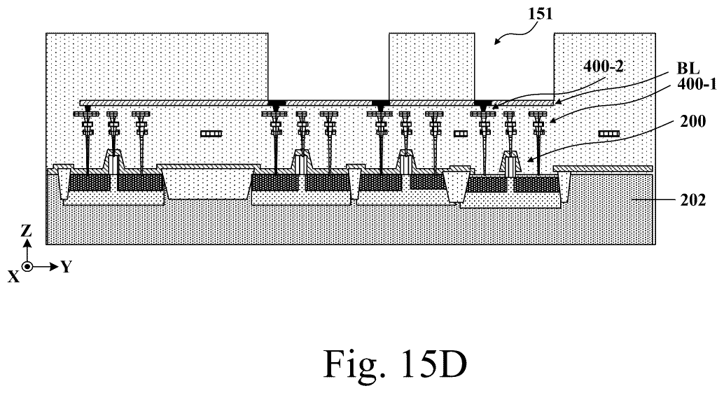

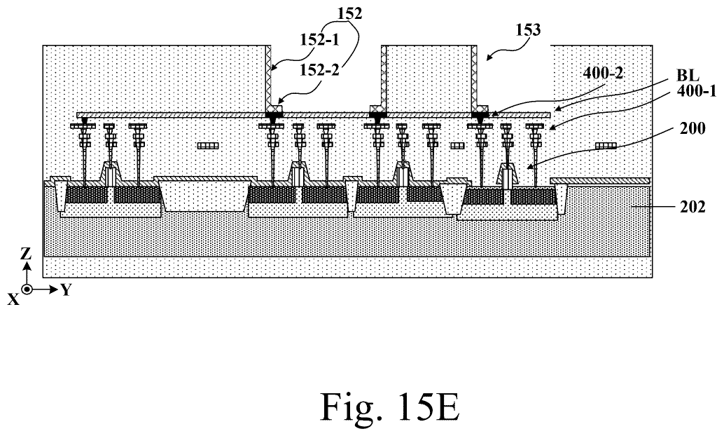

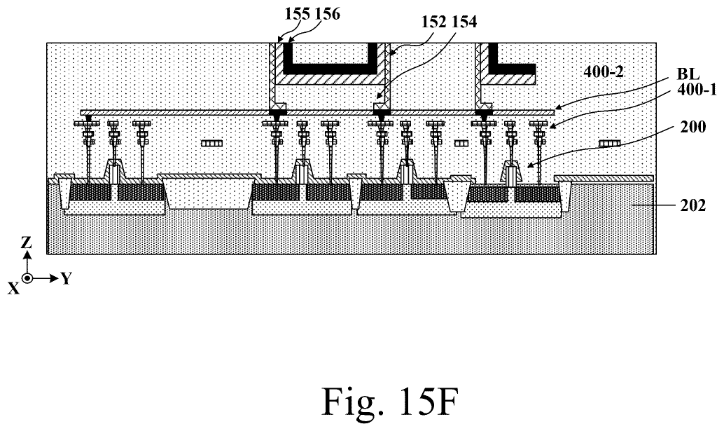

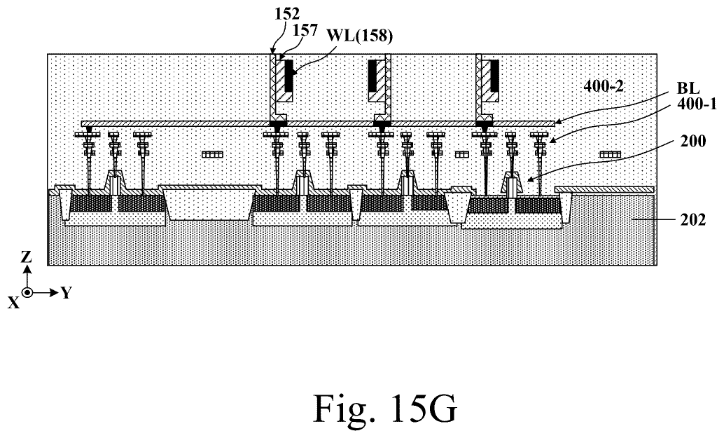

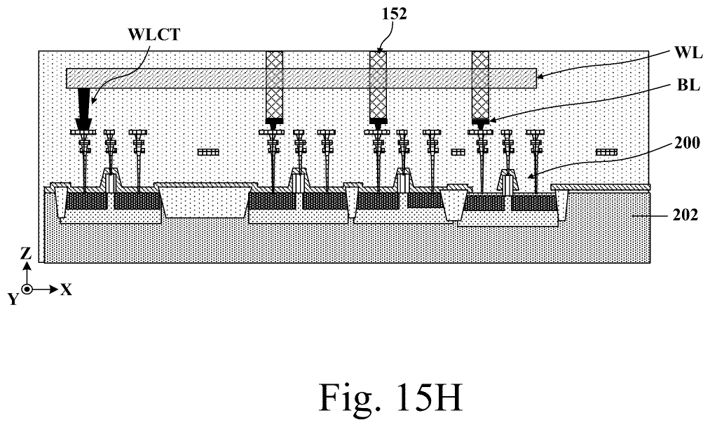

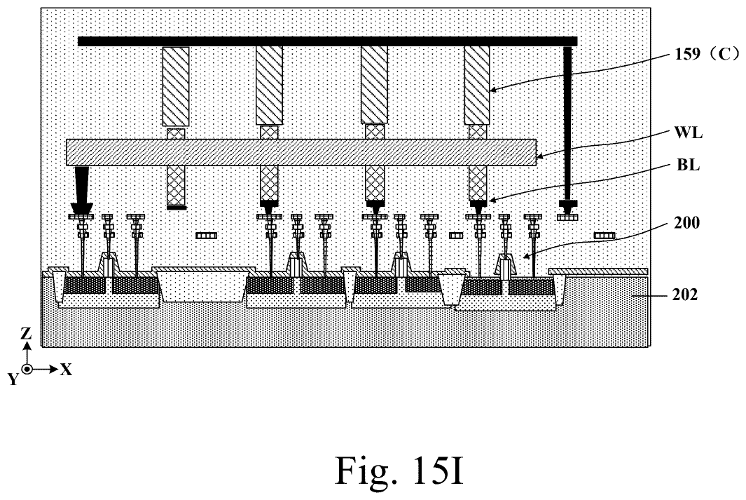

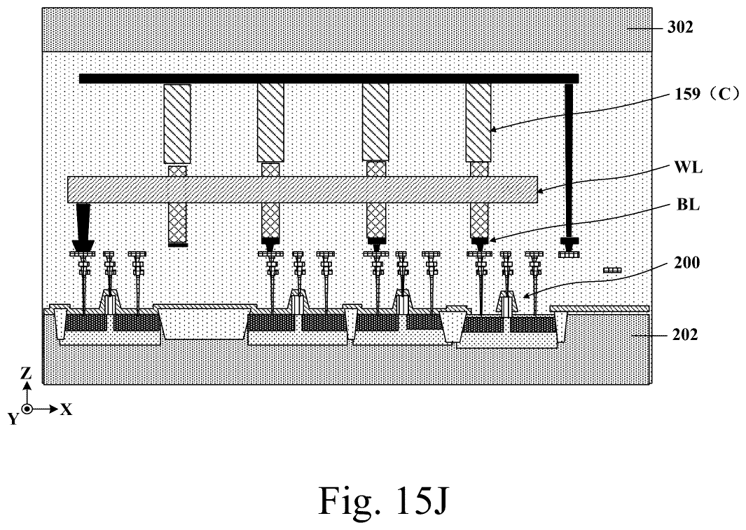

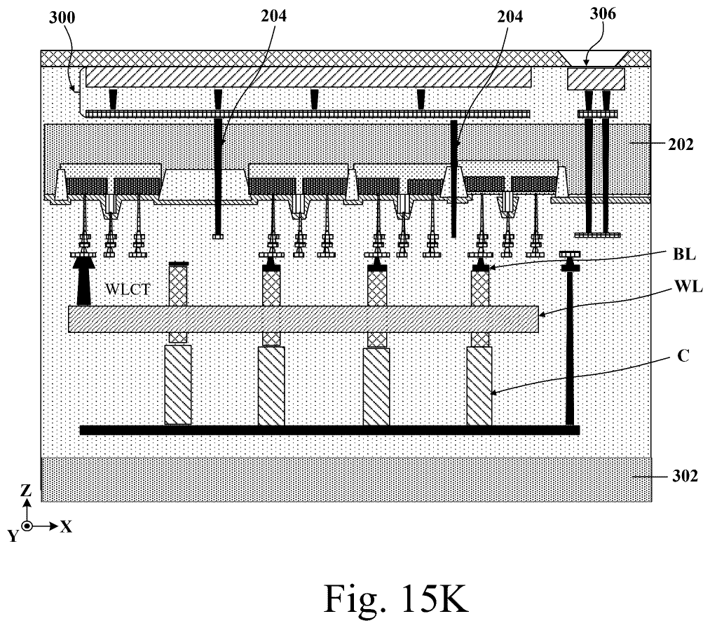

FIG. 15A to FIG. 15K are schematic cross-sectional views I in a process of forming the memory device provided by the examples of the present application. It is to be noted that FIG. 15C is a top view corresponding to a stage in FIG. 15B. The process of forming the memory device is described in detail below in conjunction with the drawings.

With reference to FIG. 15A, the first substrate 202 is provided, and the second semiconductor structure 200 is formed on the first surface of the first substrate 202. In some examples, the first substrate 202 may include a semiconductor material substrate of silicon, germanium, silicon germanium, etc., and in some other examples, the first substrate 202 may also be silicon on insulator or germanium on insulator. In some examples, the first substrate 202 has two surfaces disposed oppositely along the Z direction, wherein the first surface may be a front side of the first substrate 202, and the second surface may be a back side of the first substrate 202.

The second semiconductor structure 200 at least comprises the plurality of first control circuits and at least part of the peripheral circuit distributed in the gap of the plurality of first control circuits. In some examples, the second semiconductor structure 200 further comprises a plurality of second control circuits. The peripheral circuit, the first control circuit, and the second control circuit each may be understood with reference to the above descriptions of these circuits, and an example composition and formation position of the second semiconductor structure 200 are detailed below.

In some examples, the memory cell array comprises a plurality of memory banks, each memory bank comprising a plurality of memory blocks; one of the first control circuits is connected with one of the memory blocks, and the peripheral circuit is connected with all the memory banks; the at least part of the peripheral circuit comprises a plurality of first portions and one second portion; forming the at least part of the peripheral circuit comprises: forming one of the first portions and one of the first control circuits at a position in the second semiconductor structure that overlaps a region for disposing each of the memory blocks; and forming the second portion at a position in the second semiconductor structure that overlaps the gap between adjacent ones of the memory blocks, wherein at least one of the first portions or the second portion is connected with the first interconnection layer by the plurality of connection structures.

In some examples, the first control circuits comprise a sensing amplifier and a word line driver, wherein the sensing amplifier is connected with the bit line in the memory block, and the word line driver is connected with the word line in the memory block.

In some examples, forming the second semiconductor structure comprises: forming the sensing amplifier in a first region and a second region; and forming the word line driver in a third region and a fourth region, wherein the first region and the second region both extend along a first direction and are disposed as being staggered along a second direction, the third region and the fourth region both extend along the second direction and are disposed as being staggered along the first direction, the first direction is perpendicular to a direction in which the bit line extends, and the second direction is perpendicular to a direction in which the word line extends.

In some examples, a boundary of the first region contacts a boundary of the third region, and a boundary of the second region contacts a boundary of the fourth region; a sum of dimensions of the boundary of the first region and the boundary of the third region along the first direction is a first dimension, a dimension of a boundary of a region for disposing the memory block along the first direction is a second dimension, and the first dimension is less than the second dimension.

In some examples, the second semiconductor structure further comprises a plurality of second control circuits, one second control circuit being connected with one memory bank; and forming the second semiconductor structure further comprises: forming the at least part of the peripheral circuit and the plurality of second control circuits in the gap of the plurality of first control circuits, wherein the second control circuits comprise a row decoding circuit and a column decoding circuit. In some examples, forming the second control circuit comprises: forming the second control circuit at a position in the second semiconductor structure that overlaps the gap between adjacent ones of the memory banks.

In some examples, an example process of forming the second semiconductor structure 200 may comprise: first forming a P-type well region (PWell) and an N-type well region (NWell) on the first substrate 202, and performing n-doping in the PWell and p-doping in the NWell respectively, so as to form a desired semiconductor doped region; and then forming a gate on a surface of the substrate, so as to obtain the peripheral circuit comprising a peripheral transistor, the first control circuit, and the second control circuit.

With continued reference to FIG. 15A, a portion 400-1 of a second interconnection layer is formed on the second semiconductor structure 200. In some examples, the portion 400-1 of the second interconnection layer may comprise one or more metal layers and contacts of the respective metal layers (3 metal layers and 3-layers contacts are shown in FIG. 15A), and the portion 400-1 of the second interconnection layer is at least used for connecting transistors in the first control circuit and for leading out a source, drain and gate of a transistor contained in the first control circuit and the peripheral circuit. The portion 400-1 of the second interconnection layer comprises a third contact connected with the sensing amplifier and a fourth contact connected with the word line driver.

With reference to FIG. 15B, another portion 400-2 of the second interconnection layer and the bit line BL in the first semiconductor structure are then formed on the second semiconductor structure 200. The bit line BL extends along the second direction, i.e., the Y direction. The portion 400-1 and the other portion 400-2 of the second interconnection layer form the second interconnection layer 400 together.

In some examples, the other portion 400-2 of the second interconnection layer may comprise the word line contact, i.e., the first contact, the bit line contact, i.e., the second contact (only the bit line contact can be seen in FIG. 15B), and the capacitor common electrode contact, etc.

In some examples, a method of forming the second interconnection layer and the bit line includes, but is not limited to, first forming a trench using an etching process and then forming a metal layer and various contacts using a deposition process.

With reference to FIG. 15C, the plurality of bit lines BL all extend along the second direction, i.e., the Y direction, and are arranged as being spaced apart along the first direction. The word line contact WLCT is located on one side of the bit line and does not interfere with the bit line; other contact QTCT may be located on other side of the bit line and does not interfere with the bit line and the word line contact. It is to be noted that FIG. 15C is not a view along the Z direction corresponding to FIG. 15B, but rather a view along the Z direction of a fabrication stage corresponding to 15B. A positional relationship between the bit line, the word line contact, and the other contact illustrated in FIG. 15C is for an example purpose only and does not intend to limit a positional relationship between the bit line, the word line contact, and the other contact in the example of the present application.

With reference to FIG. 15D, a first dielectric layer is formed on a surface of the bit line BL, and a first groove 151 is formed in the first dielectric layer, wherein the first groove 151 is arranged in an array along the first direction and the second direction. In some examples, a material of the first dielectric layer includes, but is not limited to, silicon oxide, and a method of forming the dielectric layer includes, but is not limited to, a deposition process, which, in an implementation, may be a physical vapor deposition process, a chemical vapor deposition process, etc. In some examples, a method of forming the groove 151 includes, but is not limited to, a dry etching process.

With reference to FIG. 15E, a semiconductor material layer is formed on a sidewall and a bottom of the first groove 151, at least a portion of the semiconductor material layer on the bottom is removed to expose the surface of the bit line, and the remaining semiconductor material layer forms the semiconductor pillar 152. The semiconductor pillar 152 may comprise a semiconductor body 152-1 extending along the Z direction, and in an example, comprise semiconductor accessory 152-2 extending along the Y direction. A second groove 153 is formed on the basis of the first groove 151 with the semiconductor pillar 152 formed, and the second groove 153 extends along the X direction.

In some examples, a material of the semiconductor material layer may include at least one of indium gallium zinc oxide, indium zinc oxide, gallium zinc oxide, indium gallium oxide, zinc oxide, indium oxide, and gallium oxide. A method of forming the semiconductor material layer includes, but is not limited to, a deposition process. A method of removing at least a portion of the semiconductor material layer on the bottom and forming the second groove includes, but is not limited to, a dry etching process.

With reference to FIG. 15F, a dielectric material layer is formed in the second groove 153, and the dielectric material layer is etched back to form a second dielectric layer 154, wherein a top surface of the second dielectric layer 154 is lower than a top surface of the semiconductor pillar 152. A gate dielectric material layer 155, a gate material layer 156, and a dielectric material layer are formed sequentially on a top surface of the second dielectric layer 154 and on a sidewall of the second groove 153.

In some examples, a material of the dielectric material layer includes, but is not limited to, silicon oxide; a material of the gate dielectric material layer 155 includes, but is not limited to, a high dielectric material; and a material of the gate material layer 156 includes, but is not limited to, tungsten. Methods of forming the dielectric material layer, the gate dielectric material layer 155, and the gate material layer 156 include, but are not limited to, a deposition process.

With reference to FIG. 15G, portions of the gate dielectric material layer 155 and of the gate material layer 156 that are on the top surface of the second dielectric layer 154 are removed, and portions of the gate dielectric material layer 155 and of the gate material layer 156 that cover the sidewall of the second groove are etched back to form a gate dielectric layer 157 and a gate 158, i.e., the word line WL. The plurality of word lines extend along the first direction and are spaced apart along the second direction. A top surface of the gate dielectric layer 157 and a top surface of the gate 158 are lower than the top surface of the semiconductor pillar 152. In some examples, a method of removing the portions of the gate dielectric material layer 155 and of the gate material layer 156 that are on the top surface of the second dielectric layer 154 and etching back the portions of the gate dielectric material layer 155 and of the gate material layer 156 that are on the sidewall of the second groove includes, but is not limited to, dry etching.

It is to be noted that some other necessary processes, such as doping both ends of the semiconductor pillar 152 extending along the Z direction after forming the semiconductor pillar 152 to form a source and a drain, are omitted here. On that basis, the semiconductor pillar 152 is configured to form the transistor TA.

With reference to FIG. 15H, FIG. 15H is a cross-sectional view along a Z-X cross section corresponding to FIG. 15G. The word line contact WLCT can be seen in FIG. 15H. With reference to FIG. 15I, a storage structure 159 is formed on a surface of each semiconductor pillar 152 away from the bit line. In some examples, the storage structure 159 may be a capacitor. In some examples, the capacitor comprises a cup-shaped capacitor, a cylindrical capacitor, or a pillar-shaped capacitor. In some examples, a plurality of capacitors are arranged in a square or hexagon. An example form of the capacitor here may be understood with reference to the form of the capacitor mentioned above, and a method of forming the capacitor is more mature and is no longer repeated here.

It is to be noted that the number of the semiconductor pillars 152 in FIG. 15H and FIG. 15I is for an example purpose only and only intends to illustrate a general morphology of each process, in which the number of the semiconductor pillars 152 may not be illustrated equivalently. With reference to FIG. 15J, a dielectric material layer is filled, and the third substrate 302 is bonded to the dielectric material layer to form the bonding structure. It is to be noted that the third substrate 302 is used as a carrier substrate. The third substrate is not electrically constrained, as long as being firmly adhered to the dielectric material layer.

With reference to FIG. 15K, the bonding structure is flipped to expose the second surface of the first substrate 202, i.e., the back side of the first substrate, and the front side of the first substrate comprises the plurality of active regions spaced apart by the isolation regions. Starting from the back side of the first substrate, the connection structures 204 penetrating through the first substrate are formed at boundaries of the active regions (which may be understood as edges of the active regions) and in the isolation regions along the Z direction. Next, the first interconnection layer 300 is formed on the back side of the first substrate 202, and a power supply line and a wiring layer for connecting the at least part of the peripheral circuit are formed in the first interconnection layer 300. The pad 306 electrically connected with the first interconnection layer is formed on the side of the first interconnection layer away from the second semiconductor structure. In some examples, the connection structure 204 may be implemented using a through-silicon via technique.

In some examples, the third substrate 302 may also be removed selectively in a subsequent process.

Here, one fabrication method of the memory device is implemented in which the first semiconductor structure and the second semiconductor are both grown on the same substrate, i.e., the first substrate 202, so that the use of the growth substrate can be reduced to save the costs.

During the execution of operations S1401 to S1404, in some examples, forming the first semiconductor structure, the second semiconductor structure, and the first interconnection layer comprises: forming the second semiconductor structure on a first surface of a first substrate; sequentially forming a third interconnection layer and a first bonding layer that are stacked on the second semiconductor structure; forming the first semiconductor structure on a second substrate; sequentially forming a fourth interconnection layer and a second bonding layer that are stacked on the first semiconductor structure; bonding the first bonding layer and the second bonding layer, wherein the first semiconductor structure and the second semiconductor structure are connected by the third interconnection layer, the first bonding layer, the second bonding layer, and the fourth interconnection layer; and forming the first interconnection layer on a second surface of the first substrate, wherein the first surface and the second surface are two surfaces disposed oppositely along a thickness of the first substrate.

In some examples, forming the first semiconductor structure comprises: forming a plurality of storage structures on the second substrate; forming a semiconductor pillar on a surface of each storage structure away from the second substrate, the semiconductor pillar extending along a thickness direction of the second substrate; forming a plurality of word lines extending along a first direction, each word line being located on at least one side surface of the semiconductor pillar; and forming a bit line on a surface of the semiconductor pillar away from the storage structure, the bit line extending along a second direction, wherein the first direction and the second direction are both perpendicular to the thickness direction of the second substrate.

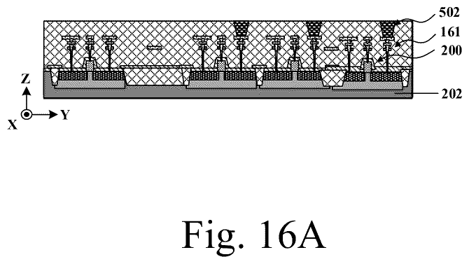

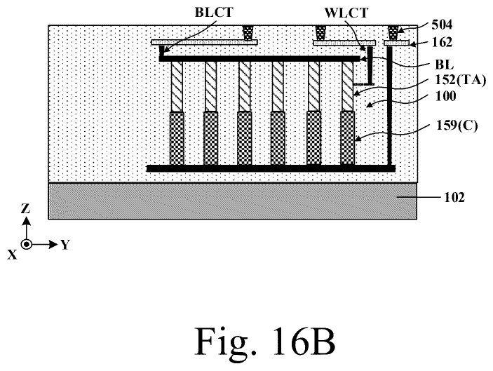

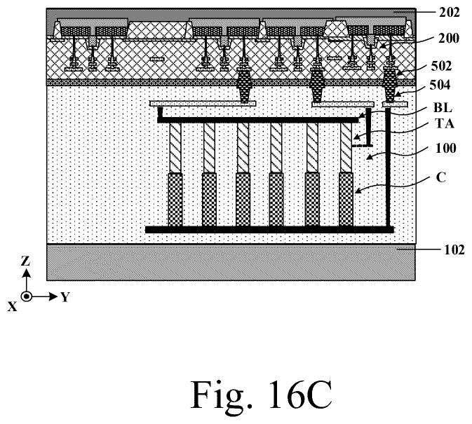

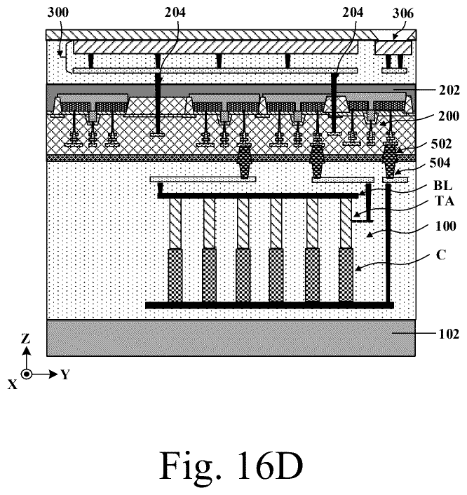

FIG. 16A to FIG. 16D are schematic cross-sectional views II in the process of forming the memory device provided by the examples of the present application. The process of forming the memory device is described in detail below in conjunction with the drawings.

With reference to FIG. 16A, the first substrate 202 is provided, and the second semiconductor structure 200 is formed on the first surface of the first substrate 202. The first substrate 202 may be understood with reference to the description mentioned above in FIG. 15A, which is no longer repeated here. Components of the second semiconductor 200, a formation position of each component, and an example formation method may be understood with reference to the description mentioned above in FIG. 15A, which are no longer repeated here.

With continued reference to FIG. 16A, the third interconnection layer and the first bonding layer that are stacked are formed sequentially on the second semiconductor structure 200. In some examples, the third interconnection layer 161 may comprise one or more metal layers and contacts of the respective metal layers (3 metal layers and 3-layers contacts are shown in FIG. 16A), and the first bonding layer may comprise the first bonding contact 502.

In some examples, a method of forming the third interconnection layer and the first bonding layer includes, but is not limited to, first forming a trench using an etching process and then forming a metal layer, and various contacts or bonding contacts using a deposition process.

With continued reference to FIG. 16B, the second substrate 102 is provided, and the first semiconductor structure 100 is formed on the second substrate 102. In an implementation, forming the first semiconductor structure 100 may comprise: forming the plurality of storage structures 159 on the second substrate 102; forming the semiconductor pillar 152 on a surface of each storage structure away from the second substrate, the semiconductor pillar extending along the thickness direction of the second substrate, i.e., the Z direction; forming a plurality of word lines WL extending along the first direction, i.e., the X direction, on at least one side surface of the semiconductor pillar 152; and forming the bit line BL extending along the second direction, i.e., the Y direction, on the surface of the semiconductor pillar away from the storage structure.

In some examples, the storage structure 159 may be a capacitor. In some examples, the capacitor comprises a cup-shaped capacitor, a cylindrical capacitor, or a pillar-shaped capacitor. In some examples, a plurality of capacitors are arranged in a square or hexagon. An example form of the capacitor here may be understood with reference to the form of the capacitor mentioned above, and a method of forming the capacitor is more mature and is no longer repeated here.

In some examples, an example method of forming the semiconductor pillar 152 and the word line WL may be understood with reference to the descriptions mentioned above in FIG. 15D to FIG. 15F, which is no longer repeated here. It is to be noted that the bit line here is formed after forming the semiconductor pillar 152, and is formed on the surface of the semiconductor pillar 152.

It is to be noted that some other necessary processes, such as doping both ends of the semiconductor pillar 152 extending along the Z direction after forming the semiconductor pillar 152 to form the source and the drain, are omitted here. On that basis, the semiconductor pillar 152 is configured to form the transistor TA.

With continued reference to FIG. 16B, the fourth interconnection layer 164 and the second bonding layer that are stacked are formed sequentially on first second semiconductor structure. In some examples, the fourth interconnection layer 164 may comprise one or more metal layers (1 metal layer and 1-layer contact are shown in FIG. 16B). The second bonding layer may comprise the second bonding contact 504.

In some examples, a method of forming the fourth interconnection layer and the second bonding layer includes, but is not limited to, first forming a trench using an etching process and then forming a metal layer, and various contacts or bonding contacts using a deposition process.

It is to be noted that the process illustrated in FIG. 16A and the process illustrated in FIG. 16B may be performed with one following the other or performed at the same time, and an order of manufacturing thereof is not limited in the examples of the present application.

With reference to FIG. 16C, the first bonding layer and the second bonding layer are bonded, and an example bonding method includes, but is not limited to, hybrid bonding. The first semiconductor structure and the second semiconductor structure are electrically connected via the third interconnection layer, the first bonding layer, the second bonding layer, and the fourth interconnection layer.

With reference to FIG. 16D, the front side of the first substrate 202 comprises the plurality of active regions spaced apart by the isolation regions. Starting from the back side of the first substrate 202, the connection structures 204 penetrating through the first substrate are formed at boundaries of the active regions (which may be understood as edges of the active regions) and in the isolation regions along the Z direction. Next, the first interconnection layer 300 is formed on the back side of the first substrate 202, and a power supply line and a wiring layer for connecting the at least part of the peripheral circuit and are formed in the first interconnection layer 300. The pad 306 electrically connected with the first interconnection layer is formed on the side of the first interconnection layer away from the second semiconductor structure. In some examples, the connection structure 204 may be implemented using a through-silicon via technique.

Here, another fabrication method of the memory device is implemented. In this method, the first semiconductor structure and the second semiconductor are grown and fabricated respectively using different substrates. As such, the problem of mutual constraints between a process of the memory cell array and a process of the peripheral circuit can be solved, thereby shortening a development cycle of the memory device.

It is to be understood that “one example” and “an example” mentioned in the whole specification mean that specific features, structures, or characteristics related to the example is included in at least one example of the present application. Therefore, “in one example” or “in an example” presented everywhere throughout this specification does not necessarily refer to the same example. Furthermore, these particular features, structures, or characteristics may be incorporated in one or more examples in any suitable manner. It is to be understood that, in various examples of the present application, sequence numbers of the above processes do not indicate an execution sequence, and an execution sequence of various processes shall be determined by functionalities and intrinsic logics thereof, and shall constitute no limitation on an implementation process of the examples of the present application. The above sequence numbers of the examples of the present application are only for description, and do not represent goodness and badness of the examples.

The above descriptions are merely implementations of the present application, and not intended to limit the patent scope of the present application. Equivalent structure transformation made using the contents of the specification and the drawings of the present application under the inventive concept of the present application, or direct/indirect application to other related technical fields are both encompassed within the patent protection scope of the present application.

What is claimed is:

1. A manufacturing method of a memory device, comprising:
forming a first semiconductor structure comprising a memory cell array;
forming a second semiconductor structure comprising first control circuits and at least part of a peripheral circuit distributed in a gap of the first control circuits, wherein the first semiconductor structure and the second semiconductor structure are disposed as being stacked and connected;
forming a first interconnection layer on a side of the second semiconductor structure away from the first semiconductor structure; and
forming connection structures, each connection structure penetrating through a portion of the second semiconductor structure, with one end being connected with the at least part of the peripheral circuit in the gap, and the other end being connected with the first interconnection layer.

2. The manufacturing method of claim 1, wherein forming the first semiconductor structure, the second semiconductor structure, and the first interconnection layer comprises:
forming the second semiconductor structure on a first surface of a first substrate;
forming a second interconnection layer on the second semiconductor structure;
forming the first semiconductor structure on the second interconnection layer, wherein the first semiconductor structure and the second semiconductor structure are connected by the second interconnection layer; and
forming the first interconnection layer on a second surface of the first substrate, wherein the first surface and the second surface are two surfaces disposed oppositely along a thickness direction of the first substrate.

3. The manufacturing method of claim 1, wherein forming the first semiconductor structure, the second semiconductor structure, and the first interconnection layer comprises:
forming the second semiconductor structure on a first surface of a first substrate;
sequentially forming a third interconnection layer and a first bonding layer that are stacked on the second semiconductor structure;
forming the first semiconductor structure on a second substrate;
sequentially forming a fourth interconnection layer and a second bonding layer that are stacked on the first semiconductor structure;
bonding the first bonding layer and the second bonding layer, wherein the first semiconductor structure and the second semiconductor structure are connected by the third interconnection layer, the first bonding layer, the second bonding layer, and the fourth interconnection layer; and
forming the first interconnection layer on a second surface of the first substrate, wherein the first surface and the second surface are two surfaces disposed oppositely along a thickness of the first substrate.

4. The manufacturing method of claim 1, wherein the memory cell array comprises memory banks, each memory bank comprising memory blocks; one of the first control circuits is connected with one of the memory blocks, and the peripheral circuit is connected with the memory banks; the at least part of the peripheral circuit comprises first portions and one second portion; forming the at least part of the peripheral circuit comprises:
forming one of the first portions and one of the first control circuits at a position in the second semiconductor structure that overlaps a region for disposing each of the memory blocks; and forming the second portion at a position in the second semiconductor structure that overlaps the gap between adjacent ones of the memory blocks, wherein at least one of the first portion or the second portion is connected with the first interconnection layer by the connection structures.

5. The manufacturing method of claim 4, wherein the first control circuits comprise a sensing amplifier and a word line driver; the sensing amplifier is connected with a bit line in the memory block; and the word line driver is connected with a word line in the memory block.

6. The manufacturing method of claim 5, wherein forming the second semiconductor structure comprises:
forming the sensing amplifier in a first region and a second region; and forming the word line driver in a third region and a fourth region, wherein the first region and the second region both extend along a first direction and are disposed as being staggered along a second direction, the third region and the fourth region both extend along the second direction and are disposed as being staggered along the first direction, the first direction is perpendicular to a direction in which the bit line extends, and the second direction is perpendicular to a direction in which the word line extends.

7. The manufacturing method of claim 6, wherein a boundary of the first region contacts a boundary of the third region, and a boundary of the second region contacts a boundary of the fourth region; a sum of dimensions of the boundary of the first region and the boundary of the third region along the first direction is a first dimension, a dimension of a boundary of the region for disposing the memory block along the first direction is a second dimension, and the first dimension is less than the second dimension.

8. The manufacturing method of claim 5, wherein the memory device further comprises a first contact connected with the word line, a second contact connected with the bit line, a third contact connected with the sensing amplifier, and a fourth contact connected with the word line driver;
the method further comprises:
forming the first contact and the second contact; and
forming the third contact and the fourth contact, wherein the second contact and the third contact, as well as the first contact and the fourth contact, are connected at least by the first interconnection layer between the first semiconductor structure and the second semiconductor structure.

9. The manufacturing method of claim 1, further comprising:
forming a power supply line in the first interconnection layer.

10. The manufacturing method of claim 4, wherein the second semiconductor structure further comprises second control circuits, one of the second control circuits being connected with one of the memory banks; and forming the second semiconductor structure further comprises:
forming the at least part of the peripheral circuit and the second control circuits in the gap of the first control circuits, wherein the second control circuits comprise a row decoding circuit and a column decoding circuit.

11. The manufacturing method of claim 10, wherein forming the second control circuits comprises:
forming the second control circuits at a position in the second semiconductor structure that overlaps a gap between adjacent ones of the memory banks.

12. The manufacturing method of claim 1, further comprising:
forming a pad electrically connected with the first interconnection layer on a side of the first interconnection layer away from the second semiconductor structure.

13. The manufacturing method of claim 2, wherein the first surface of the first substrate comprises active regions spaced apart by isolation regions; and the method further comprises:
forming the connection structures penetrating through the first substrate at boundaries of the active regions and in the isolation regions.

14. The manufacturing method of claim 2, wherein forming the first semiconductor structure comprises:
forming bit lines extending along a second direction;
forming semiconductor pillars on surfaces of the bit lines, each semiconductor pillar extending along the thickness direction of the first substrate;
forming word lines extending along a first direction, each word line being located on at least one side surface of the semiconductor pillar, wherein the first direction and the second direction are both perpendicular to the thickness direction of the first substrate; and
forming a storage structure on a surface of each of the semiconductor pillars away from the bit line.

15. The manufacturing method of claim 14, further comprising:
providing a third substrate;
bonding the third substrate to the storage structure to form a bonding structure;
flipping the bonding structure to expose the second surface of the first substrate; and
removing the third substrate after forming the first interconnection layer on the second surface of the first substrate.

16. The manufacturing method of claim 3, wherein forming the first semiconductor structure comprises:
forming storage structures on the second substrate;
forming a semiconductor pillar on a surface of each of the storage structures away from the second substrate, the semiconductor pillar extending along a thickness direction of the second substrate;
forming word lines extending along a first direction, each word line being located on at least one side surface of the semiconductor pillar; and
forming a bit line on a surface of the semiconductor pillar away from the storage structure, the bit line extending along a second direction, wherein the first direction and the second direction are both perpendicular to the thickness direction of the second substrate.

17. The manufacturing method of claim 14, wherein the memory device comprises a dynamic random access memory; the storage structure comprises a capacitor; and the capacitor comprises a cup-shaped capacitor, a cylindrical capacitor, or a pillar-shaped capacitor.

18. The manufacturing method of claim 16, further comprising:
forming the storage structures arranged in a square or hexagon.

19. The manufacturing method of claim 14, wherein forming the word lines comprises:
forming the word lines located on one side surface of the semiconductor pillar;
forming the word lines located on two side surfaces of the semiconductor pillar that are disposed oppositely; or
forming the word lines surrounding the side surfaces of the semiconductor pillar.

20. The manufacturing method of claim 14, wherein a material of the semiconductor pillar comprises indium gallium zinc oxide.
